(19) United States
(12) Patent Application Publication
(10) Pub. No.: US 2026/0157073 A1
(43) Pub. Date: Jun. 4, 2026

(54) TRANSPARENT DISPLAY APPARATUS

(71) Applicant: LG Display Co., Ltd., Seoul (KR)

(72) Inventor: HwiDeuk LEE, Paju-si (KR)

(73) Assignee: LG Display Co., Ltd., Seoul (KR)

(21) Appl. No.: 19/349,139

(22) Filed: Oct. 3, 2025

(30) Foreign Application Priority Data
Dec. 2, 2024 (KR) 10-2024-0176312

(51) Int. Cl. H10K 59/40; G06F 3/044; H10K 59/131; H10K 59/35; H10K 59/80; H10K 102/10

(52) U.S. Cl. CPC H10K 59/40; G06F 3/0446; H10K 59/1315; H10K 59/353; H10K 59/80521; H10K 59/8792; H10K 2102/101

(57) ABSTRACT

A transparent display apparatus in one or more examples may include: a substrate; a display area in which a transmissive area and a plurality of subpixels are arranged; a non-display area surrounding the display area; a black matrix arranged on the substrate and between the plurality of subpixels and the transmissive area, and between the plurality of subpixels; a main touch electrode partially overlapping the black matrix; and an auxiliary touch electrode extending from the main touch electrode and arranged in the transmissive area.

### CROSS-REFERENCE TO RELATED APPLICATIONS

This application claims the benefit of and priority to Korean Patent Applications No. 10-2024-0176312 filed on Dec. 2, 2024, the entire contents of which are incorporated herein by reference for all purposes as if fully set forth herein.

### BACKGROUND

### 1. Technical Field

The present disclosure relates to a transparent display apparatus.

### 2. Discussion of Related Art

With the advancement of the information age, the demand for a display apparatus for displaying an image has increased in various forms. Therefore, various types of display apparatuses such as a liquid crystal display (LCD) device, a plasma display panel (PDP) device, a quantum dot light emitting display (QLED) device and an organic light emitting display (OLED) device have been recently used.

Meanwhile, recently, studies for a transparent display apparatus in which a user may view objects or images positioned at an opposite side by transmitting the display apparatus are actively ongoing.

The transparent display apparatus includes a display area where an image is displayed and a non-display area, and the display area may include a transmissive area that can transmit external light. These transparent display apparatus has the problem of making touch implementation difficult due to the transmissive area.

The description of related art should not be considered prior art merely because it is mentioned in or associated with this section. The description of related art includes information that describes one or more aspects of the subject technology, and the description in this section does not limit the scope of the invention

### SUMMARY

An aspect of the present disclosure is to provide a transparent display apparatus capable of implementing touch while minimizing reduction in transmittance.

Further, an aspect of the present disclosure is to provide a transparent display apparatus capable of improving touch sensitivity.

Further, an aspect of the present disclosure is to provide a transparent display apparatus that can be implemented over a large area while minimizing bezel increase.

Further, an aspect of the present disclosure is to provide a transparent display apparatus in which production energy can be reduced through process optimization.

The problems to be solved by the examples of the present disclosure are not limited to those mentioned above, and other problems not mentioned will be apparent to one of ordinary skill in the art to which the technical spirits of the present disclosure belong from the following description.

A transparent display apparatus according to an embodiment of the present disclosure comprises: a substrate; a display area in which a transmissive area and a plurality of subpixels are arranged; a non-display area surrounding the display area; a black matrix arranged on the substrate and between the plurality of subpixels and the transmissive area, and between the plurality of subpixels; a main touch electrode partially overlapping the black matrix; and an auxiliary touch electrode extending from the main touch electrode and arranged in the transmissive area.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a schematic plan view showing a transparent display apparatus according to one embodiment of the present disclosure.

FIG. 2 is a schematic plan view showing the structure of a touch electrode of a transparent display apparatus according to one embodiment of the present disclosure.

FIG. 3 is an enlarged view of part A of FIG. 2.

FIG. 4 is a cross-sectional view showing one example of I-I′ of FIG. 3.

FIG. 5 is a perspective view showing a transparent display apparatus according to the second embodiment of the present disclosure.

FIG. 6 is a schematic illustration showing a transparent display panel of a transparent display apparatus according to the second embodiment of the present disclosure.

FIG. 7 is a schematic plan view partially showing the structure of a touch electrode of a transparent display apparatus according to the second embodiment of the present disclosure.

FIG. 8 is a schematic plan view showing one pixel of a transparent display apparatus according to the second embodiment of the present disclosure.

FIG. 9 is a cross-sectional view showing one example of II-II′ of FIG. 8.

FIG. 10 is a cross-sectional view showing one example of III-III′ of FIG. 5.

FIG. 11 is a schematic illustration showing a transparent display panel including a touch electrode of a transparent display apparatus according to the second embodiment of the present disclosure.

FIG. 12 is an enlarged view of part B of FIG. 7.

FIG. 13 is an enlarged view of part C of FIG. 7.

FIG. 14 is a partial cross-sectional view showing one example of IV-IV′ of FIG. 13.

FIG. 15 is a partial cross-sectional view showing another example of IV-IV′ of FIG. 13.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely one example, and thus, the present disclosure is not limited to the illustrated details.

Like reference numerals refer to like elements throughout. In the following description, when the detailed description of the relevant known function or configuration is determined to unnecessarily obscure the important point of the present disclosure, the detailed description will be omitted.

In a case where “comprise,” “have,” and “include” described in the present disclosure are used, another part may be added unless “only” is used. The terms of a singular form may include plural forms unless referred to the contrary. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In construing an element, the element is construed as including an error range although there is no explicit description.

In describing a position relationship, for example, when a position relation between two parts is described as “on,” “over,” “under,” and “next,” one or more other parts may be disposed between the two parts unless “just” or “direct” is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

“X-axis direction,” “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the preferred embodiments of the present disclosure will be described in detail with reference to the accompanying drawings.

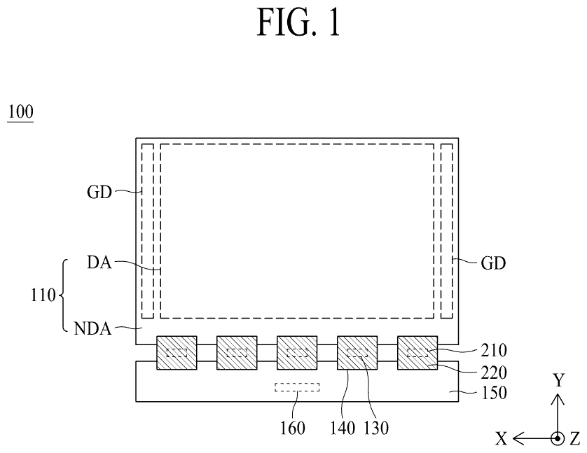

FIG. 1 is a schematic plan view showing a transparent display apparatus according to one embodiment of the present disclosure.

Hereinafter, an X-axis direction represents a horizontal direction (or a direction parallel to a gate line) of a transparent display apparatus based on FIG. 1, a Y-axis direction represents a vertical direction (or a direction parallel to the data line) of a transparent display apparatus based on FIG. 1, and a Z-axis represents a thickness direction (or a height direction) of a transparent display apparatus 100.

The following description will be based on that a transparent display apparatus 100 according to one embodiment of the present disclosure is an organic light emitting display apparatus, but is not limited thereto. That is, the transparent display apparatus according to one embodiment of the present disclosure may be implemented as any one of a liquid crystal display apparatus, a plasma display apparatus, a quantum dot lighting emitting diode apparatus, and an electrophoretic display apparatus as well as the organic light emitting display apparatus.

Referring to FIG. 1, a transparent display apparatus 100 according to one embodiment of the present disclosure may include a transparent display panel, a source drive integrated circuit (hereinafter IC) 130, a flexible film 140, and a circuit boards 150, and a timing controller 160.

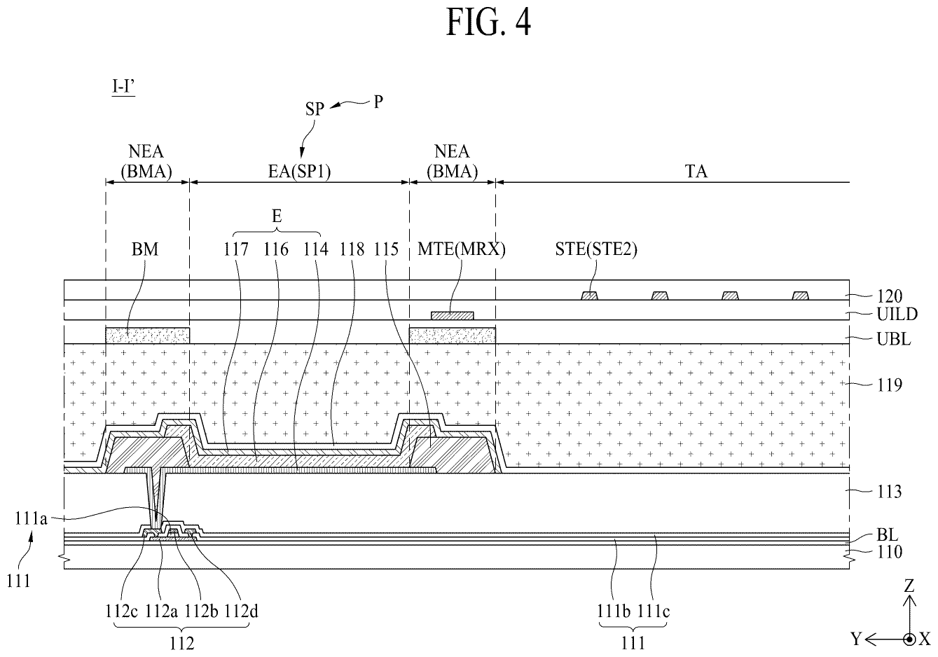

The transparent display panel may include a substrate 110 and an encapsulation film 120 (shown in FIG. 4).

The substrate 110 may include a thin film transistor, and may be a transistor array substrate, a lower substrate, a base substrate, or a first substrate. The substrate 110 may be a transparent glass substrate or a transparent plastic substrate. The substrate 110 may include a display area DA and a non-display area NDA.

The display area DA is an area where an image is displayed, and may be a pixel array area, an active area, a pixel array unit, a display unit, or a screen. For example, the display area DA may be disposed at a central portion of the display panel. The display area DA may include a transmissive area TA and a plurality of pixels P.

The encapsulation film 120 may be an upper substrate, a second substrate, or an opposing substrate. The encapsulation film 120 may be a plastic film or a glass substrate. The encapsulation film 120 (or opposing substrate) can be sequentially formed on a light-emitting element after the light-emitting element is formed on the substrate 110. The substrate 110 and the encapsulation film 120 can be made of transparent materials.

The gate driver GD supplies gate signals to the gate lines according to gate control signals input from the timing controller 160. The gate driver GD may be formed in a gate driver in panel GIP manner in the non-display area NDA on either outer side of the display area DA of the transparent display panel. Alternatively, the gate driver GD may be made of a driving chip, mounted on a flexible film, and attached to the non-display areas NDA on both outer sides of the display area DA of the display panel by a TAB (tape automated bonding) method.

The non-display area NDA may be an area where an image is not displayed, and may be a peripheral circuit area, a signal supply area, a non-active area, or a bezel area. The non-display area NDA may be configured to be around the display area DA. That is, the non-display area NDA may be disposed to surround the display area DA. A pad section for supplying power and/or signals for outputting images to pixels P provided in the display area DA may be placed in the non-display area NDA.

The source drive IC 130 receives digital video data and a source control signal from the timing controller 160. The source drive IC 130 converts the digital video data into analog data voltages in accordance with the source control signal and supplies the analog data voltages to the data lines. When the source drive IC 130 is manufactured as a driving chip, the source drive IC 130 may be packaged in the flexible film 140 in a chip on film (COF) method or a chip on plastic (COP) method.

Pads, such as data pads, may be formed in the non-display area NDA. Lines connecting the pads with the source drive IC 130 and lines connecting the pads with lines of the circuit board 150 may be formed in the flexible film 140. The flexible film 140 may be attached onto the pads by using an anisotropic conducting film, whereby the pads may be connected with the lines of the flexible film 140.

The circuit board 150 may be attached to the flexible films 140. A plurality of circuits implemented as driving chips may be packaged in the circuit board 150. For example, the timing controller 160 may be packaged in the circuit board 150. The circuit board 150 may be a printed circuit board or a flexible printed circuit board.

The timing controller 160 receives the digital video data and a timing signal from an external system board through a cable of the circuit board 150. The timing controller 160 generates a gate control signal for controlling an operation timing of the gate driver GD and a source control signal for controlling the source drive ICs 130 based on the timing signal. The timing controller 160 supplies the gate control signal to the gate driver GD, and supplies the source control signal to the source drive ICs 130.

Pads, such as power pads, data pads, may be formed in the non-display area of the transparent display panel. Lines connecting the pads with the source drive IC 130 and lines connecting the pads with lines of the circuit board 150 may be formed in the flexible film 140. The flexible film 140 may be attached onto the pads by using an anisotropic conducting film, whereby the pads may be connected with the lines of the flexible film 140.

The transparent display apparatus 100 according to one embodiment of the present disclosure may further include a printed circuit board 220 equipped with a touch driver 210. The touch driver 210 is for sensing touch or supplying a touch driving signal from a plurality of touch electrodes provided on the transparent display panel. For example, the touch electrodes may include a plurality of main touch electrodes MTE and a plurality of auxiliary touch electrodes STE. The plurality of touch electrodes can be connected to a plurality of lower pads formed on the substrate 110, and the plurality of lower pads can be connected to a printed circuit board 220 equipped with the touch driver 210 through a plurality of lines. The printed circuit board 220 may be placed adjacent to the flexible film 140 on which the source drive IC 130 is mounted. For example, the printed circuit board 220 may be placed at an edge of the circuit board 150, as shown in FIG. 1. However, the present invention is not limited thereto, and the printed circuit board 220 may be placed at a center area of the circuit board 150, or at an another area other than the center area and the edge.

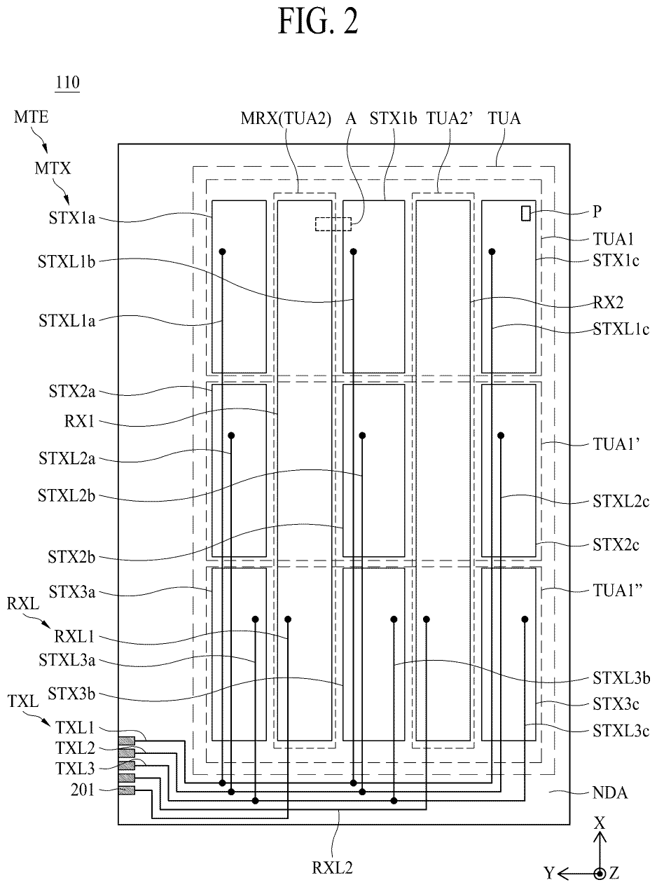

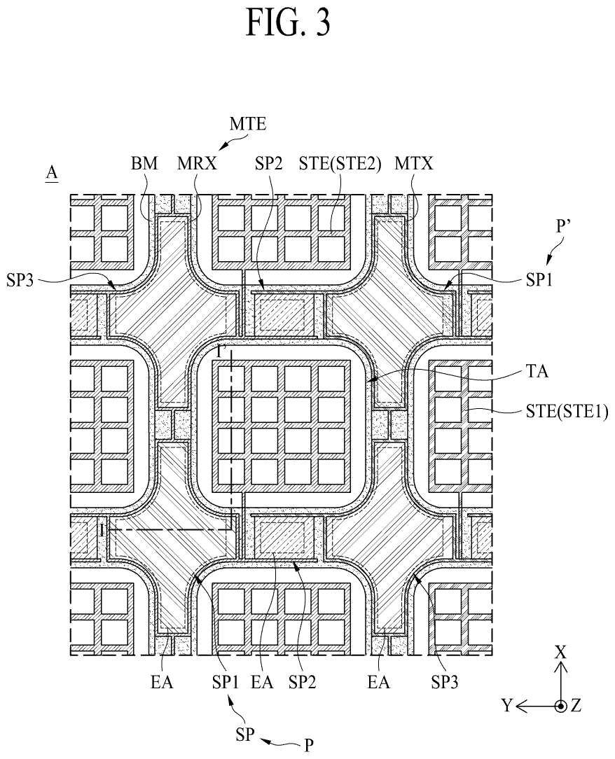

FIG. 2 is a schematic plan view showing the structure of a touch electrode of a transparent display apparatus according to one embodiment of the present disclosure, FIG. 3 is an enlarged view of part A of FIG. 2, and FIG. 4 is a cross-sectional view showing one example of I-I′ of FIG. 3.

Referring to FIG. 2, the transparent display apparatus 100 according to one embodiment of the present disclosure can sense touch by being provided with the touch electrodes. For example, when a user's finger or a touch pen used by a user comes into contact with the transparent display apparatus 100 according to one embodiment of the present disclosure, the transparent display apparatus 100 according to one embodiment of the present disclosure can sense the user's touch.

Since the transparent display apparatus 100 according to one embodiment of the present disclosure can be provided with the transparent display panel in a mutual manner, some of the plurality of touch electrodes can be included in a touch driving electrodes, and other touch electrodes can be included in a touch receiving electrodes. That is, the transparent display panel may include the touch driving electrodes and the touch receiving electrodes.

The plurality of touch electrodes according to one example may include a plurality of main touch electrodes MTE and a plurality of auxiliary touch electrodes STE. The plurality of main touch electrodes MTE and the plurality of auxiliary touch electrodes STE can be provided on the top of the light emitting element layer E (shown in FIG. 4) of the substrate 110.

The plurality of main touch electrodes MTE may include a plurality of first main touch electrodes MTX and a plurality of second main touch electrodes MRX. According to one example, the plurality of first main touch electrodes MTX can be the touch driving electrodes, and the plurality of second main touch electrodes MRX can be the touch receiving electrodes. However, the present invention is not necessarily limited thereto.

The plurality of auxiliary touch electrodes STE may include a plurality of first auxiliary touch electrodes STE1 (shown in FIG. 3) and a plurality of second auxiliary touch electrodes STE2 (shown in FIG. 3). The plurality of first auxiliary touch electrodes STE1 can be connected to the plurality of first main touch electrodes MTX. For example, each of the plurality of first auxiliary touch electrodes STE1 may be electrically connected to each of the plurality of first main touch electrodes MTX, or two or more first auxiliary touch electrodes STE1 may be electrically connected to one first main touch electrode MTX. The plurality of second auxiliary touch electrodes STE2 can be connected to the plurality of second main touch electrodes MRX. For example, each of the plurality of second auxiliary touch electrodes STE2 may be electrically connected to each of the plurality of second main touch electrodes MRX, or two or more second auxiliary touch electrodes STE2 may be electrically connected to one second main touch electrode MRX.

As illustrated in FIG. 2, the transparent display panel (or substrate 110) may include the first main touch electrodes MTX provided spaced apart along a first direction (e.g., Y-axis direction) and the second main touch electrodes MRX provided extending along a second direction (e.g., X-axis direction) different from the first direction.

The transparent display panel (or substrate 110) may be provided with at least two first main touch electrodes MTX and at least two second main touch electrodes MRX. As illustrated in FIG. 2, the plurality of first main touch electrodes MTX and the plurality of second main touch electrodes MRX may be provided in a touch area TUA. Hereinafter, for convenience of explanation, the transparent display panel equipped with three first main touch electrodes MTX and two second main touch electrodes MRX as illustrated in FIG. 2 is described as one example.

As shown in FIG. 2, the touch area TUA may include a first touch area TUA1, an another first touch area TUA1′, and an another first touch area TUA1″. Three first main touch electrodes MTX can be arranged in each of the first touch area TUA1, the another first touch area TUA1′, and the another first touch area TUA1″. The first touch area TUA1, the another first touch area TUA1', and the another first touch area TUA1″ can be spaced apart from each other in the second direction (X-axis direction).

The touch area TUA may further include a second touch area TUA2 and an another second touch area TUA2′. Each of the two second main touch electrodes MRX may be disposed in the second touch area TUA2 and the another second touch area TUA2′. The second touch area TUA2 and the another second touch area TUA2′ can be spaced apart from each other in the first direction (Y-axis direction).

Each of the first main touch electrodes MTX can be connected to a touch driver 210 (or a plurality of pads 201 connected to the touch driver 210) through a touch driving electrode line TXL. And, each of the second main touch electrodes MRX can be connected to the touch driver 210 (or the plurality of pads 201 connected to the touch driver 210) through a touch receiving electrode line RXL.

For example, each of the plurality of first main touch electrodes MTX in each of the first touch area TUA1, the another first touch area TUA1′, and the another first touch area TUA1″ can be connected to the touch driver 210 (or the plurality of pads 201 connected to the touch driver 210) through the first touch driving electrode line TXL1 to the third touch driving electrode line TXL3.

For example, the first main touch electrode MTX in the first touch area TUA1 may include a 1a sub-touch driving electrode STX1a, a 1b sub-touch driving electrode STX1b, and a 1c sub-touch driving electrode STX1c. The 1a sub-touch driving electrode STX1a, the 1b sub-touch driving electrode STX1b, and the 1c sub-touch driving electrode STX1c may be provided spaced apart from each other along the first direction (Y-axis direction). The 1a sub-touch driving electrode STX1a can be connected to the first touch driving electrode line TXL1 via a 1a touch line STXL1a. The 1b sub-touch driving electrode STX1b can be connected to the first touch driving electrode line TXL1 via the 1b touch line STXL1b. The 1c sub-touch driving electrode STX1c can be connected to the first touch driving electrode line TXL1 via the 1c touch line STXL1c. Accordingly, the 1a sub-touch driving electrode STX1a, the 1b sub-touch driving electrode STX1b, and the 1c sub-touch driving electrode STX1c can be electrically connected to each other in the non-display area NDA. The 1a touch line STXL1a, the 1b touch line STXL1b, and the 1c touch line STXL1c can be arranged in parallel along the first direction (Y-axis direction).

The first main touch electrode MTX in the another first touch area TUA1′ may include a 2a sub-touch driving electrode STX2a, a 2b sub-touch driving electrode STX2b, and a 2c sub-touch driving electrode STX2c. The 2a sub-touch driving electrode STX2a, the 2b sub-touch driving electrode STX2b, and the 2c sub-touch driving electrode STX2c may be provided spaced apart from each other along the first direction (Y-axis direction). The 2a sub-touch driving electrode STX2a can be connected to the second touch driving electrode line TXL2 via a 2a touch line STXL2a. The 2b sub-touch driving electrode STX2b can be connected to the second touch driving electrode line TXL2 via a 2b touch line STXL2b. The 2c sub-touch driving electrode STX2c can be connected to the second touch driving electrode line TXL2 via a 2c touch line STXL2c. Accordingly, the 2a sub-touch driving electrode STX2a, the 2b sub-touch driving electrode STX2b, and the 2c sub-touch driving electrode STX2c can be electrically connected to each other in the non-display area NDA. The 2a touch line STXL2a, the 2b touch line STXL2b, and the 2c touch line STXL2c can be arranged in parallel along the second direction (X-axis direction).

The first main touch electrode MTX in the another first touch area TUA1'′ may include a 3a sub-touch driving electrode STX3a, a 3b sub-touch driving electrode STX3b, and a 3c sub-touch driving electrode STX3c. The 3a sub-touch driving electrode STX3a, the 3b sub-touch driving electrode STX3b, and the 3c sub-touch driving electrode STX3c may be provided spaced apart from each other along the first direction (Y-axis direction). The 3a sub-touch driving electrode STX3a can be connected to the third touch driving electrode line TXL3 via a 3a touch line STXL3a. The 3b sub-touch driving electrode STX3b can be connected to the third touch driving electrode line TXL3 via a 3b touch line STXL3b. The 3c sub-touch driving electrode STX3c can be connected to the third touch driving electrode line TXL3 via a 3c touch line STXL3c. Accordingly, the 3a sub-touch driving electrode STX3a, the 3b sub-touch driving electrode STX3b, and the 3c sub-touch driving electrode STX3c can be electrically connected to each other in the non-display area NDA. The third touch line STXL3a, the third touch line STXL3b, and the third touch line STXL3c can be arranged in parallel along the second direction (X-axis direction).

The transparent display apparatus 100 according to one embodiment of the present disclosure is provided such that sub-touch driving electrodes in each of the first touch area TUA1, the another first touch area TUA1′, and the another first touch area TUA1″ are connected to the touch driving electrode lines (e.g., the first touch driving electrode line TXL1) in a non-display area NDA through a plurality of touch lines (e.g., the 1a touch line STXL1a) arranged in a second direction (X-axis direction), so that a decrease in the transmittance of the transmissive area TA can be minimized while touch can be implemented compared to a case where the sub-touch driving electrodes in the display area DA (or touch area TUA) are connected to each other through a plurality of touch lines arranged in the first direction (Y-axis direction).

If the sub-touch driving electrodes in each of the first touch area TUA1, the another first touch area TUA1′, and the another first touch area TUA1″ are connected to each other through a plurality of touch lines crossing in the first direction (Y-axis direction), a section in which the plurality of touch lines and the sub-touch driving electrodes intersect and overlap occurs, and in this case, the touch load may increase.

Therefore, the transparent display apparatus 100 according to one embodiment of the present disclosure is provided with a structure in which sub-touch driving electrodes in each of the first touch area TUA1, the another first touch area TUA1′, and the another first touch area TUA1″ are connected to each other in the non-display area NDA through a plurality of touch lines (e.g., the 1a touch line STXL1a) and the touch driving electrode lines (e.g., the first touch driving electrode line TXL1) arranged in the second direction (X-axis direction), thereby preventing the plurality of touch lines and the sub-touch driving electrodes from crossing and overlapping, thereby preventing an increase in touch load.

Meanwhile, the second main touch electrode MRX in the second touch area TUA2 may include a first touch receiving electrode RX1. The first touch receiving electrode RX1 may be connected to the touch driver 210 (or the plurality of pads 201 connected to the touch driver 210) through a first touch receiving electrode line RXL1. The second main touch electrode MRX in the another second touch area TUA2′ may include a second touch receiving electrode RX2. The second touch receiving electrode RX2 can be connected to the touch driver 210 (or the plurality of pads 201 connected to the touch driver 210) through the second touch receiving electrode line RXL2. The first touch receiving electrode RX1 and the second touch receiving electrode RX2 may be provided to extend along the second direction (X-axis direction) and to be spaced apart from each other in the first direction (Y-axis direction).

As shown in FIG. 2, a part of the first touch receiving electrode RX1 may be disposed between the 1a sub-touch driving electrode STX1a and the 1b sub-touch driving electrode STX1b of the first main touch electrode MTX, which are spaced apart from each other. A part of the second touch receiving electrode RX2 may be disposed between the 1b sub-touch driving electrode STX1b and the 1c sub-touch driving electrode STX1c of the first main touch electrode MTX, which are spaced apart from each other.

The first main touch electrodes MTX and the second main touch electrodes MRX can be provided on the transparent display panel (or substrate 110) in various structures as long as they can sense the user's touch.

Meanwhile, one second main touch electrode MRX can be arranged lengthwise in the second direction (X-axis direction) between two sub-touch driving electrodes (for example, the 1a sub-touch driving electrode STX1a and the 1b sub-touch driving electrode STX1b). Accordingly, the second touch area TUA2 can be provided in a stripe shape. According to one example, a length of the second direction (X-axis direction) of the second main touch electrode MRX may be formed to be greater than a length of the second direction (X-axis direction) of the sub-touch driving electrode (for example, the 1a sub-touch driving electrode STX1a). For example, the length of the second direction (X-axis direction) of the second main touch electrode MRX may be formed to be the same as or similar to a length of the second direction (X-axis direction) of three sub-touch driving electrodes (e.g., the 1a sub-touch driving electrode STX1a, the 2a sub-touch driving electrode STX2a, and the 3a sub-touch driving electrode STX3a) provided in a row along the second direction (X-axis direction).

In contrast, the sub-touch driving electrodes (for example, the 1a sub-touch driving electrode STX1a, the 1b sub-touch driving electrode STX1b, and the 1c sub-touch driving electrode STX1c) provided in the first touch area TUA1 may be arranged to be spaced apart from each other along the first direction (Y-axis direction). Accordingly, the first touch area TUA1 may be provided in a split form.

Meanwhile, as the area of the transparent display apparatus increases, a length in the second direction (X-axis direction) may increase, and thus, a length of the transparent display panel (or substrate 110) in the second direction (X-axis direction) may also increase.

When a length of the second direction (X-axis direction) of the transparent display panel increases, a length of a second direction (X-axis direction) of one second main touch electrode MRX provided along the second direction (X-axis direction) can increase.

When the length of the second direction (X-axis direction) of the second main touch electrode MRX increases, the size and sensitivity of the touch sensing signal generated from the second main touch electrode MRX and transmitted to the touch driver 210 may vary depending on the location where the touch occurs.

To prevent this, the transparent display apparatus 100 according to the second embodiment of the present disclosure may have at least two second main touch electrodes MRX arranged in a row along the second direction (X-axis direction). In this case, each of at least two second main touch electrodes MRX may be formed to have a length in the second direction (X-axis direction) that is identical to or similar to the length of three sub-touch actuation electrodes arranged in a row along the second direction (X-axis direction).

In the following description, an area provided with the first main touch electrodes MTX and the second main touch electrodes MRX is referred to as a touch area TUA, and an area not provided with the first main touch electrodes MTX and the second main touch electrodes MRX is referred to as a non-touch area. For example, the non-touch area may be the non-display area NDA.

Meanwhile, each of the sub-touch driving electrodes of the first main touch electrode MTX in the first touch area TUA1 can be connected to the touch driver 210 through one first touch driving electrode line TXL1.

As the area of the transparent display apparatus increases, a distance between the first main touch electrode MTX in the first touch area TUA1 and the touch driver 210 may increase, and a length of the first main touch electrode MTX in the first touch area TUA1 may increase.

Accordingly, a size of the touch driving signal may vary depending on the location of the first main touch electrode MTX, and thus, a size and sensitivity of a touch sensing signal may vary depending on a location of the first main touch electrode MTX (or the sub touch driving electrodes STX1a, STX1b, STX1c) in the first touch area TUA1.

To prevent this, in the transparent display apparatus 100 according to one embodiment of the present disclosure, as illustrated in FIG. 2, each of the first touch lines STXL1a, STXL1b, STXL1c connected to the sub-touch driving electrodes STX1a, STX1b, STX1c in the first touch area TUA1 among the first main touch electrodes MTX can extend along the second direction (X-axis direction).

In this case, the first touch lines STXL1a, STXL1b, STXL1c can be connected to the first touch driving electrode line TXL1 in the non-touch area (or non-display area NDA), and the first touch driving electrode line TXL1 can be connected to the touch driver 210. As a result, as shown in FIG. 2, the first touch lines STXL1a, STXL1b, STXL1c can be arranged in parallel while extending in the second direction (X-axis direction).

This structure can be equally applied to the second touch lines STXL2a, STXL2b, STXL2c and the third touch lines STXL3a, STXL3b, STXL3c. However, since the sub-touch driving electrodes STX2a, STX2b, STX2c in the another first touch area TUA1′ based on FIG. 2 are arranged closer to the non-display area NDA below the substrate 110 than the sub-touch driving electrodes STX1a, STX1b, STX1c in the first touch area TUA1, a length of each of the second touch lines STXL2a, STXL2b, STXL2c may be shorter than a length of each of the first touch lines STXL1a, STXL1b, STXL1c. In addition, since the sub-touch driving electrodes STX3a, STX3b, STX3c in the another first touch area TUA1″ are arranged closer to the non-display area NDA below the substrate 110 than the sub-touch driving electrodes STX2a, STX2b, STX2c in the second touch area TUA1′, a length of each of the third touch lines STXL3a, STXL3b, STXL3c can be provided to be shorter than a length of each of the second touch lines STXL1a, STXL1b, STXL1c.

As shown in FIG. 2, since lengths of each of the first touch lines STXL1a, STXL1b, STXL1c are the same, the resistance characteristics of each of the first touch lines STXL1a, STXL1b, STXL1c can become the same or similar, and accordingly, the characteristics of the touch driving signals supplied to the sub-touch driving electrodes can become the same or similar. This can be equally applied to the sub-touch driving electrodes connected to each of the second touch lines STXL2a, STXL2b, STXL2c, the second touch lines STXL2a, STXL2b, STXL2c, the sub-touch driving electrodes connected to each of the third touch lines STXL3a, STXL3b, STXL3c, and the third touch lines STXL3a, STXL3b, STXL3c.

Each of the second main touch electrodes MRX may be connected to the touch receiving electrode line RXL extending along the second direction (X-axis direction). The touch receiving electrode line RXL may also extend along the second direction (X-axis direction) in the touch area TUA.

When at least two second main touch electrodes MRX are provided along the second direction (X-axis direction), a touch receiving electrode line RXL extending along the second direction (X-axis direction) may be connected to each of the at least two second main touch electrodes MRX. For example, in the touch area TUA of the transparent display panel illustrated in FIG. 2, each of the first touch receiving electrode line RXL1 and the second touch receiving electrode line RXL2 may be arranged in parallel while extending along the second direction (X-axis direction).

A length of the first touch receiving electrode line RXL1 and a length of the second touch receiving electrode line RXL2 may be different from each other. However, the length of the first touch receiving electrode line RXL1 and the length of the second touch receiving electrode line RXL2 can be formed to be the same so that a resistance characteristic of the first touch receiving electrode line RXL1 and a resistance characteristic of the second touch receiving electrode line RXL2 can be the same or similar.

Meanwhile, the transparent display apparatus 100 according to one embodiment of the present disclosure can be equipped with a mutual method using the main touch electrode MTE and the auxiliary touch electrode STE, and thus can be implemented as a transparent display apparatus capable of double-sided touch.

Hereinafter, the plurality of pixel P structures of the transparent display apparatus 100 according to one embodiment of the present disclosure will be specifically described with reference to FIG. 3.

Referring to FIG. 3, the transparent display apparatus 100 according to one embodiment of the present disclosure may include a substrate 110 including a transmissive area TA and a plurality of subpixels SP, a black matrix BM, a main touch electrode MTE, and an auxiliary touch electrode STE. The black matrix BM is arranged on the substrate 110 and can be arranged between the plurality of subpixels SP and the transmissive area TA, and between the plurality of subpixels SP. The main touch electrode MTE may partially overlap with the black matrix BM. The auxiliary touch electrode STE may extend from the main touch electrode MTE and be arranged in the transmissive area TA.

As shown in FIG. 3, the main touch electrode MTE may not overlap any of the plurality of subpixels SP. For example, the main touch electrode MTE may include a first main touch electrode MTX and a second main touch electrode MRX, and each of the first main touch electrode MTX and the second main touch electrode MRX may be arranged so as not to overlap each of the plurality of subpixels SP. When the main touch electrode MTE overlaps with the plurality of subpixels SP (or a light emission area EA of each of the plurality of subpixels SP), light emitted from each of the plurality of subpixels SP (or the light emission area EA of each of the plurality of subpixels SP) interferes with the main touch electrode MTE, thereby reducing light efficiency. Accordingly, the transparent display apparatus 100 according to one embodiment of the present disclosure is provided so that the main touch electrode MTE does not overlap any of the plurality of subpixels SP, thereby preventing a decrease in light efficiency.

According to one example, the main touch electrode MTE may be provided to partially overlap with the black matrix BM. That is, the main touch electrode MTE may be partially placed in a non-light emission area NEA (shown in FIG. 4) where light is not emitted. Accordingly, the transparent display apparatus 100 according to one embodiment of the present disclosure is provided such that the main touch electrode MTE partially overlaps the black matrix BM, so that the main touch electrode MTE may not cover the transmissive area TA, thereby enabling touch to be implemented while minimizing reduction in transmittance.

Meanwhile, the main touch electrode MTE according to one example may be an opaque conductive material. For example, the main touch electrode MTE may be made of a low-resistance metal such as aluminum, copper, or an alloy including these. The auxiliary touch electrode STE according to one example may be a transparent conductive material. For example, the auxiliary touch electrode STE may be made of a high-resistance metal such as ITO or IZO. In the transparent display apparatus 100 according to one embodiment of the present disclosure, the main touch electrode MTE that is opaque and has low resistance may be provided so as to partially overlap the black matrix BM. Accordingly, the transparent display apparatus 100 according to one embodiment of the present disclosure can improve touch sensitivity while minimizing reduction in transmittance.

Referring again to FIG. 3, the plurality of subpixels SP according to one example may include a first subpixel SP1, a second subpixel SP2, and a third subpixel SP3. The first subpixel SP1, the second subpixel SP2, and the third subpixel SP3 can be sequentially arranged in the first direction (Y-axis direction). As shown in FIG. 3, each of the first subpixel SP1 and the third subpixel SP3 may have a cross shape, and the second subpixel SP2 may have a square shape. Accordingly, as shown in FIG. 3, the first subpixel SP1 and the third subpixel SP3 may have a symmetrical shape with the second subpixel SP2 interposed therebetween. The first subpixel SP1, the second subpixel SP2, and the third subpixel SP3 may be included in one pixel P. For example, the first subpixel SP1 may be a green subpixel, the second subpixel SP2 may be a red subpixel, and the third subpixel SP3 may be a blue subpixel.

Meanwhile, another pixel P′ adjacent to one pixel P in the second direction (X-axis direction) may include a first subpixel SP1, a second subpixel SP2, and a third subpixel SP3. However, the first subpixel SP1, the second subpixel SP2, and the third subpixel SP3 included in an another pixel P′ may have an arrangement structure that is opposite to the first subpixel SP1, the second subpixel SP2, and the third subpixel SP3 included in one pixel P in the first direction (Y-axis direction). However, the arrangement structure of the plurality of subpixels may be variously changed.

As shown in FIG. 3, one transmissive area TA can be surrounded by the first subpixel SP1, the second subpixel SP2, and the third subpixel SP3 included in one pixel P and the first subpixel SP1, the second subpixel SP2, and the third subpixel SP3 included in the another pixel P'.

Referring to FIG. 3, the transparent display apparatus 100 according to one embodiment of the present disclosure may include the auxiliary touch electrode STE positioned in the transmissive area TA. According to one example, the auxiliary touch electrode STE may be provided in a mesh shape. Since the auxiliary touch electrode STE is provided in a mesh form, external light can be transmitted through a plurality of holes formed inside the auxiliary touch electrode STE, so that the reduction in transmittance can be minimized. In addition, the transparent display apparatus 100 according to one embodiment of the present disclosure may have improved touch sensitivity by having the auxiliary touch electrode STE in the transmissive area TA. A touch signal sensed through the auxiliary touch electrode STE can be transmitted to the touch driver 210 through the main touch electrode MTE.

Meanwhile, an edge of the auxiliary touch electrode STE may be provided in a closed loop shape. As a result, the edge of the auxiliary touch electrode STE may be provided uniformly in a straight shape. If the edge of the auxiliary touch electrode is irregularly provided with a rough structure, a clarity of the background or image may be reduced due to a diffraction phenomenon of external light. Accordingly, in the transparent display apparatus 100 according to one embodiment of the present disclosure, since the edge of the auxiliary touch electrode STE arranged in the transmissive area TA is provided in the closed loop shape, the diffraction phenomenon can be minimized or prevented, and thus a deterioration of the clarity of the background or image on a back of the transparent display apparatus can be prevented.

Hereinafter, referring to FIG. 4, a structure of each of the plurality of subpixels SP will be described in detail.

Referring to FIG. 4, the transparent display apparatus 100 according to one embodiment of the present disclosure may include a buffer layer BL, a circuit element layer 111 (or an inorganic film layer), a thin film transistor 112, an overcoat layer 113, a pixel electrode 114, a bank 115, an organic light emitting layer 116, a cathode electrode 117, an encap layer 118, and an encapsulation layer 119.

In more detail, one (e.g., the first subpixel SP1) of the plurality of subpixels SP may include a circuit element layer 111 provided on an upper surface of a buffer layer BL, including a gate insulating layer 111a, an interlayer insulating layer 111b and a passivation layer 111c, an overcoat layer 113 provided on the circuit element layer 111, a pixel electrode 114 provided on the overcoat layer 113, a bank 115 covering an edge of the pixel electrode 114, an organic light emitting layer 116 on the pixel electrode 114 and the bank 115, a cathode electrode 117 on the organic light emitting layer 116, an encap layer 118 on the cathode electrode 117, and an encapsulation layer 119 on the encap layer 118.

The thin film transistor 112 for driving the subpixel SP may be disposed on the circuit element layer 111. The circuit element layer 111 may be expressed as the term of an inorganic film layer. The buffer layer BL may be included in the circuit element layer 111 together with the gate insulating layer 111a, the interlayer insulating layer 111b and the passivation layer 111c. The pixel electrode 114, the organic light emitting layer 116 and the cathode electrode 117 may be included in the light emitting element layer E.

The buffer layer BL may be formed between the substrate 110 and the gate insulating layer 111a to protect the thin film transistor 112. The buffer layer BL may be disposed on the entire surface (or front surface) of the substrate 110. The buffer layer BL may serve to block diffusion of a material contained in the substrate 110 into a transistor layer during a high temperature process of a manufacturing process of the thin film transistor. Optionally, the buffer layer BL may be omitted in some cases.

The thin film transistor 112 (or a drive transistor) according to one example may include an active layer 112a, a gate electrode 112b, a source electrode 112c, and a drain electrode 112d.

The active layer 112a may include a channel area, a drain area and a source area, which are formed in a thin film transistor area of a circuit area of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As one example, the gate insulating layer 111a may be formed in an island shape only on the channel area of the active layer 112a, or may be formed on an entire front surface of the substrate 110 or the buffer layer BL, which includes the active layer 112a.

The gate electrode 112b may be formed on the gate insulating layer 111a to overlap the channel area of the active layer 112a.

The interlayer insulating layer 111b may be formed on the gate electrode 112b and the drain area and the source area of the active layer 112a. The interlayer insulating layer 111b may be formed over the entire non-light emission area NEA (or a black matrix area BMA) and the light emission area EA, as shown in FIG. 4. However, embodiments of the present disclosure are not limited thereto, the interlayer insulating layer 111b may be patterned between the drain electrode 112d and the gate electrode 112b and drain area of the active layer 112a and may be arranged in an island shape, and moreover, may be patterned between the source electrode 112c and the gate electrode 112b and source area of the active layer 112a and may be arranged in an island shape.

The source electrode 112c may be electrically connected to the source area of the active layer 112a through a source contact hole provided in the interlayer insulating layer 111b overlapped with the source area of the active layer 112a. The drain electrode 112d may be electrically connected to the drain area of the active layer 112a through a drain contact hole provided in the interlayer insulating layer 111b overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode.

In addition, the circuit area may further include first and second switching thin film transistors disposed together with the thin film transistor 112, and a capacitor. Since each of the first and second switching thin film transistors is provided on the circuit area (or the black matrix area BMA) of the subpixel SP to have the same structure as that of the thin film transistor 112, its description will be omitted. The capacitor (not shown) may be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the transparent display panel or the substrate 110 may further include a light shielding layer (not shown) provided below the active layer 112a of at least one of the thin film transistor 112, the first switching thin film transistor or the second switching thin film transistor. The light shielding layer may be disposed between the substrate 110 and the active layer 112a to shield light incident on the active layer 112a through the substrate 110, thereby minimizing a change in the threshold voltage of the transistor due to external light. Also, since the light shielding layer is provided between the substrate 110 and the active layer 112a, the thin film transistor may be prevented from being seen by a user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL.

Meanwhile, the transparent display apparatus 100 according to one embodiment of the present disclosure may be provided so that the bank 115 is arranged on one side of the light emission area EA and the other side of the light emission area EA. For example, one side of the light emission area EA may mean a left area adjacent to a left side of the light emission area EA of FIG. 4. And, the other side of the light emission area EA may mean a right area adjacent to a right side of the light emission area EA of FIG. 4. The passivation layer 111c may be formed over the entire circuit area and the light emission area. The passivation layer 111c may be omitted. The overcoat layer 113 may be disposed on the passivation layer 111c.

The overcoat layer 113 may be provided on the substrate 110 to cover the passivation layer 111c. When the passivation layer 111c is omitted, the overcoat layer 113 may be provided on the substrate 110 to cover the circuit area. The overcoat layer 113 may be formed in the entire circuit area in which the thin film transistor 112 is disposed and the light emission area EA. In addition, the overcoat layer 113 may be formed in the other non-display area NDA except a pad area of the non-display area NDA and the entire display area DA. For example, the overcoat layer 113 may include an extension portion (or an enlarged portion) extended or enlarged from the display area DA to the other non-display area NDA except the pad area. Therefore, the overcoat layer 113 may have a size relatively wider than that of the display area DA.

The overcoat layer 113 according to one example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin.

Referring again to FIG. 4, the pixel electrode 114 may be placed on the overcoat layer 113. Since an upper surface of the overcoat layer 113 is provided flat, the pixel electrode 114 formed on the overcoat layer 113 can also be provided in a flat shape. Additionally, the organic light-emitting layer 116 and the cathode electrode 117 formed on the pixel electrode 114 can also be provided in a flat shape. Since the pixel electrode 114, the organic light emitting layer 116, the cathode electrode 117, that is, the light emitting element layer E is provided to be flat in the light emission area EA, a thickness of each of the pixel electrode 114, the organic light emitting layer 116 and the cathode electrode 117 in the light emission area EA may be uniformly formed. Therefore, the organic light emitting layer 116 may be uniformly emitted without deviation in the light emission area EA.

The pixel electrode 114 may be connected to a drain electrode or a source electrode of the thin film transistor 112 through a contact hole passing through the overcoat layer 113 and the passivation layer 111c. Each of one edge portion of the pixel electrode 114 and the other edge portion of the pixel electrode 114 can be covered by the bank 115.

According to one example, the pixel electrode 114 may include a metal material. The pixel electrode 114 can reflect light emitted from the organic light-emitting layer 116 in each of the plurality of subpixels SP toward an upper side of the substrate 110, i.e., toward the encapsulation film 120 (or the opposite substrate).

Since the transparent display apparatus 100 according to one embodiment of the present disclosure is a top emission type and the light emitted from the organic light-emitting layer 116 must be reflected toward the encapsulation film 120 (or the opposite substrate), the pixel electrode 114 may be made of a metal material with high reflectivity. According to one example, the pixel electrode 114 may be formed of a metal material having a high reflectivity, such as a laminated structure (Ti/Al/Ti) of aluminum and titanium, a laminated structure (ITO/Al/ITO) of aluminum and ITO, an Ag alloy, and a laminated structure (ITO/Ag alloy/ITO) of Ag alloy and ITO. The Ag alloy may be an alloy of a silver, a palladium, and a copper. The pixel electrode 114 may be expressed in terms of a first electrode and an anode electrode.

The bank 115 is an area where light is not emitted, and can be provided on one side and the other side of the light emission area EA of each of the plurality of subpixels SP. For example, the bank 115 may be placed in the non-light emission area NEA that overlaps the circuit area. The circuit area may be an area equipped with the thin film transistor 112. As shown in FIG. 4, the bank 115 can be formed so that one edge of the pixel electrode 114 of each of the subpixels SP covers the portion connected to the thin film transistor 112. Additionally, the bank 115 may be formed to cover the other edge of the pixel electrode 114 of each of the subpixels SP. That is, the bank 115 can partially cover the pixel electrode 114. Accordingly, the bank 115 can prevent the pixel electrode 114 and the cathode electrode 117 from coming into contact in the non-light emission area NEA overlapping the circuit area, and can prevent the pixel electrode 114 and the cathode electrode 117 from coming into contact in the non-light emission area NEA adjacent to the other side of the light emission area EA. An exposed portion of the pixel electrode 114 that is not covered by the bank 115 may be included in the light-emitting portion (or the light emission area EA).

After the bank 115 is formed, an organic light emitting layer 116 may be formed to cover the pixel electrodes 114 and a part of the bank 115. Thus, the bank 115 may be provided between the pixel electrodes 114 and the organic light emitting layer 116. The bank 115 may be expressed in terms of a pixel-defining membrane. The bank 115 according to one example may comprise organic material and/or inorganic material.

The organic light-emitting layer 116 can be formed between the pixel electrode 114 and the cathode electrode 117. As shown in FIG. 4, the organic light-emitting layer 116 according to one example may be placed in a part of the non-light emission area NEA and the light emission area EA. Since the organic light-emitting layer 116 is provided between the pixel electrode 114 and the cathode electrode 117, when different voltages are applied to each of the pixel electrode 114 and the cathode electrode 117, an electric field is formed between the pixel electrode 114 and the cathode electrode 117, so that the organic light-emitting layer 116 can emit light.

In the transparent display apparatus 100 according to one embodiment of the present disclosure, the organic light-emitting layer 116 may be formed in a pattern on each of a plurality of subpixels SP. Accordingly, each of the organic light-emitting layer 116 in the first sub-pixel SP1, the organic light-emitting layer 116 in the second sub-pixel SP2, and the organic light-emitting layer 116 in the third sub-pixel SP3 may be provided with a structure that is disconnected from each other (or a discontinuous structure). As described above, since the first subpixel SP1 is a green subpixel, the organic light-emitting layer 116 in the first subpixel SP1 may be a green light-emitting layer. Since the second subpixel SP2 is a red subpixel, the organic light-emitting layer 116 in the second subpixel SP2 may be a red light-emitting layer. Since the third subpixel SP3 is a blue subpixel, the organic light-emitting layer 116 in the third subpixel SP3 may be a blue light-emitting layer.

As a result, the transparent display apparatus 100 according to one embodiment of the present disclosure may be provided such that the organic light-emitting layer 116 disposed in each of the plurality of subpixels SP emits different colors. Since the organic light-emitting layer 116 arranged in each of the plurality of subpixels SP is provided to emit different colors, the transparent display apparatus 100 according to one embodiment of the present disclosure may not be provided with a color filter.

The cathode electrode 117 may be formed on the organic light-emitting layer 116. The cathode electrode 117 may be placed in the light emission area EA and the non-light emission area NEA. According to one example, the cathode electrode 117 may not be placed in the transmissive area TA. Accordingly, the transparent display apparatus 100 according to one embodiment of the present disclosure can have improved transmittance of the transmissive area TA compared to a case where the cathode electrode is arranged in the transmissive area. The cathode electrode 117 can be made of at least one of a transparent metal material and a semi-transparent metal material.

Since the transparent display apparatus 100 according to one embodiment of the present disclosure is formed in the top emission type, the cathode electrode 117 may be formed of a transparent metal material TCO (or Transparent Conductive Material) such as ITO or IZO that can transmit light, or a semi-transmissive metal material (or Semi-transmissive Conductive Material) such as magnesium Mg, silver Ag, or an alloy of magnesium Mg and silver Ag.

An encap layer 118 is formed on the cathode electrode 117. The encap layer 118 serves to prevent oxygen or moisture from penetrating into the organic light-emitting layer 116 and the cathode electrode 117. To this end, the encap layer 118 may be arranged as a common layer in the light emission area EA, the non-light emission area NEA, and the transmissive area TA. According to one example, the encap layer 118 may include an inorganic film and/or an organic film.

An encapsulation layer 119 is formed on the encap layer 118. The encapsulation layer 119, like the encap layer 118, serves to prevent oxygen or moisture from penetrating into the organic light-emitting layer 116 and the cathode electrode 117. To this end, the encapsulation layer 119 may include at least one inorganic film and at least one organic film.

Meanwhile, as shown in FIG. 4, the encapsulation layer 119 may be placed not only in the light emission area EA but also in the non-light emission area NEA. The encapsulation layer 119 may be placed between the encapsulation layer 118 and the encapsulation film 120 (or the opposing substrate).

Referring to FIG. 4, the transparent display apparatus 100 according to one embodiment of the present disclosure may further include a black matrix BM, an upper buffer layer UBL, an upper insulating layer UILD, a main touch electrode MTE, an auxiliary touch electrode STE, and an encapsulation film 120 (or an opposing substrate).

The black matrix BM can be placed on the encapsulation layer 119. The black matrix BM is intended to prevent color mixing between adjacent subpixels. According to one example, the black matrix BM may be placed at a position corresponding to the bank 115. In FIG. 4, a width of the black matrix BM and a width of the bank 115 are shown to be the same, but this is not limited thereto. The black matrix BM may be made of a material that absorbs or blocks light. An area where the black matrix BM is arranged may be a black matrix area BMA, and the black matrix area BMA may be the non-light emissive area NEA.

The upper buffer layer UBL may be arranged on the black matrix BM. The upper buffer layer UBL may be provided to cover the black matrix BM. The upper buffer layer UBL may be arranged over the entire lower surface of the encapsulation film 120 (or the opposing substrate). Optionally, the upper buffer layer UBL may be omitted in some cases.

In the transparent display apparatus 100 according to one embodiment of the present disclosure, the main touch electrode MTE may be disposed on the black matrix BM. For example, as shown in FIG. 4, the second main touch electrode MRX may be disposed on the black matrix BM. Due to this, the main touch electrode MTE may not overlap (or interfere with) the transmissive area TA. As described above, since the main touch electrode MTE is made of an opaque, low-resistance metal, when the main touch electrode MTE overlaps the transmissive area TA, the transmittance of the transmissive area TA may be significantly reduced. However, since the transparent display apparatus 100 according to one embodiment of the present disclosure is provided so that the main touch electrode MTE is disposed on the black matrix BM, the touch electrode can be provided without interference with the transmissive area TA, and thus, it can be implemented as a touch transparent display apparatus in which the reduction in transmittance is minimized or prevented. In addition, the transparent display apparatus 100 according to one embodiment of the present disclosure may not have its light efficiency reduced because the main touch electrode MTE is disposed on the black matrix BM and thus does not interfere with the light emission area EA. In addition, the transparent display apparatus 100 according to one embodiment of the present disclosure can have improved touch sensitivity because the main touch electrode MTE is made of a low-resistance metal.

The upper insulating layer UILD can be disposed on the main touch electrode MTE. For example, the upper insulating layer UILD can be provided as a common layer over the entire light emission area EA, non-light emission area NEA, and transmissive area TA while covering the main touch electrode MTE. The upper insulating layer UILD serves to prevent oxygen or moisture from penetrating the main touch electrode MTE.

The auxiliary touch electrode STE may be placed on the upper insulating layer UILD. The auxiliary touch electrode STE is for sensing a user's touch. Accordingly, the auxiliary touch electrode STE may be electrically connected to the main touch electrode MTE. According to one example, the auxiliary touch electrode STE can be provided in a mesh form and can be placed in the transmissive area TA. In a transparent display apparatus 100 according to one embodiment of the present disclosure, the auxiliary touch electrode STE is made of a transparent conductive material, so that a decrease in the transmittance of the transmissive area TA can be minimized. As shown in FIG. 3, a transparent display apparatus 100 according to one embodiment of the present disclosure may have improved touch sensitivity by having the auxiliary touch electrodes STE provided in each of a plurality of transmissive areas TA.

Meanwhile, since the auxiliary touch electrode STE is disposed on the upper insulating layer UILD, the transparent display apparatus 100 according to one embodiment of the present disclosure may have a structural feature in which the auxiliary touch electrode STE is disposed further away from the substrate 110 than the main touch electrode MTE. In the transparent display apparatus 100 according to one embodiment of the present disclosure, the auxiliary touch electrode STE is positioned further away from the substrate 110 than the main touch electrode MTE, so that the auxiliary touch electrode STE is positioned relatively close to the encapsulation film 120 adjacent to the outside, so that even a subtle touch can be detected, thereby maximizing touch sensing.

The encapsulating film 120 (or opposing substrate) can encapsulate (or seal) the display area DA placed on the substrate 110. For example, the encapsulating film 120 may be formed on the upper insulating layer UILD so as to cover the auxiliary touch electrode STE after the auxiliary touch electrode STE is formed. According to one example, the encapsulating film 120 may be composed of multiple layers, such as an organic protective layer thicker than a metal layer, to improve encapsulating performance. However, it is not necessarily limited to this, and the encapsulating film 120 may be provided as a single thin layer so as to detect even a fine touch.

Unlike a general transparent display apparatus formed by bonding a lower substrate on which a light-emitting element layer is formed and an upper substrate on which a black matrix is formed, the transparent display apparatus 100 according to one embodiment of the present disclosure may be formed by sequentially depositing the light-emitting element layer E, the encapsulation layer 119, the main touch electrode MTE, the auxiliary touch electrode STE, and the encapsulation film 120 on the substrate 110. Accordingly, since the transparent display apparatus 100 according to one embodiment of the present disclosure is not equipped with a bonded structure and is therefore easy to manufacture, it can be usefully used as a small-to medium-sized transparent display apparatus rather than a large-area transparent display apparatus. For example, the transparent display apparatus 100 according to one embodiment of the present disclosure can be used as a transparent display apparatus applied to an automobile.

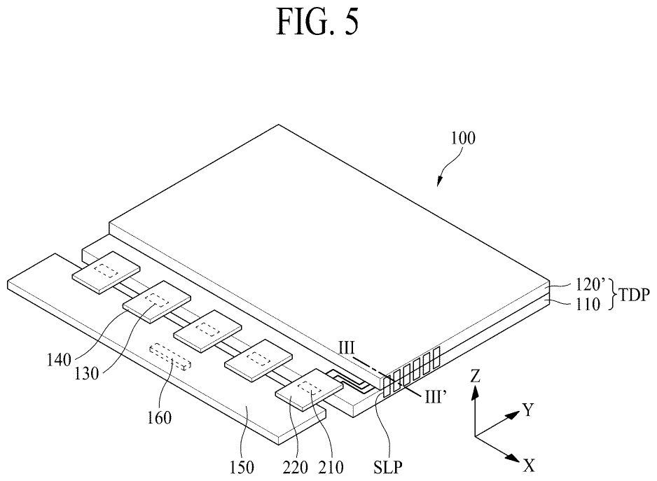

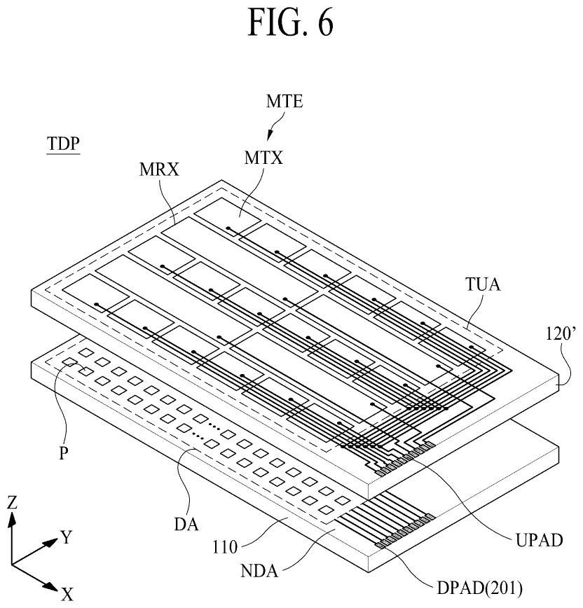

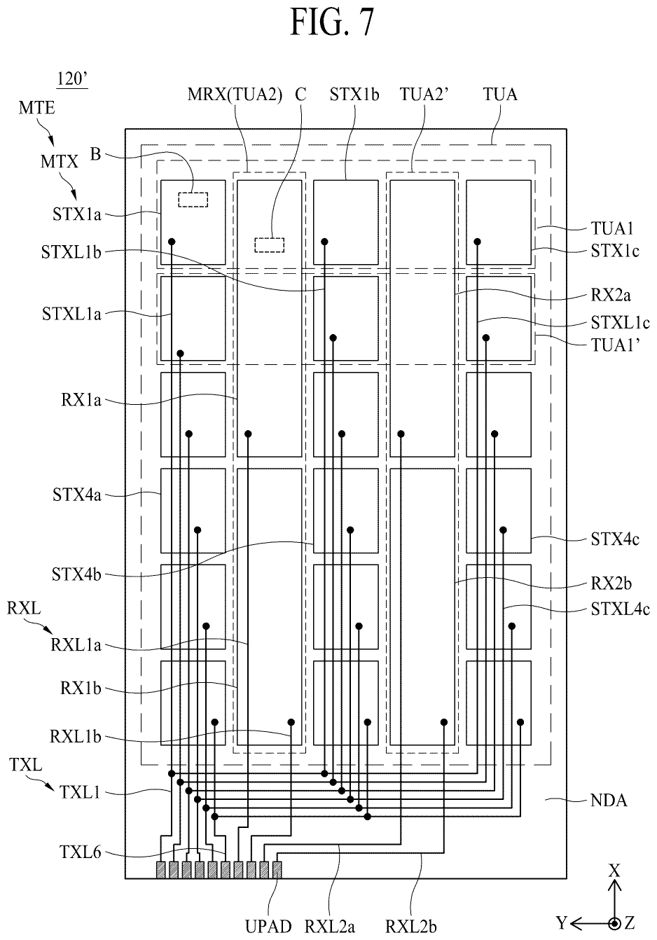

FIG. 5 is a perspective view showing a transparent display apparatus according to the second embodiment of the present disclosure, FIG. 6 is a schematic illustration showing a transparent display panel of a transparent display apparatus according to the second embodiment of the present disclosure, and FIG. 7 is a schematic plan view partially showing the structure of a touch electrode of a transparent display apparatus according to the second embodiment of the present disclosure.

Referring to FIGS. 5 to 7, the transparent display apparatus 100 according to the second embodiment of the present disclosure is the same as the display apparatus according to FIG. 1 described above, except that the structure of the transparent display panel is changed. Therefore, the same drawing symbols have been assigned to the same configuration, and only the different configurations will be described hereinafter.

In the case of the transparent display apparatus according to FIG. 1, the light emitting element layer E, the encapsulation layer 119, the main touch electrode MTE, the auxiliary touch electrode STE, and the encapsulation film 120 can be sequentially deposited and formed on the substrate 110. Accordingly, in the case of the transparent display apparatus according to FIG. 1, since the substrate 110 and the encapsulation film 120 are not bonded to each other, not only is manufacturing easy, but foreign substances from the outside can be prevented from being included inside the transparent display panel during the manufacturing process, so reliability can be improved.

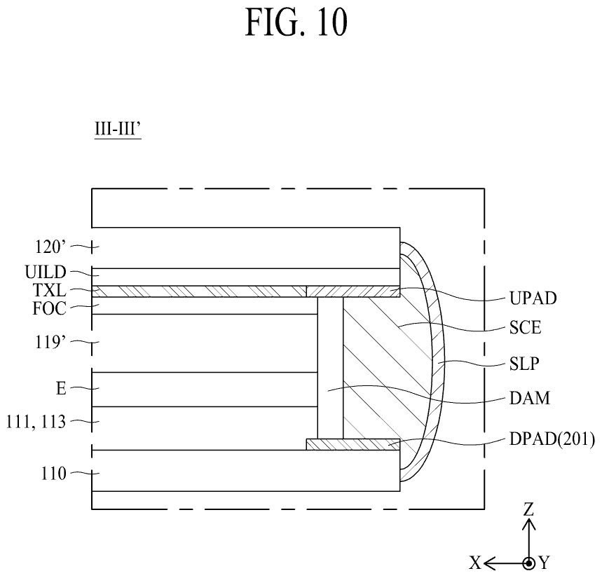

In contrast, in the case of the transparent display apparatus according to FIG. 5, the transparent display panel TDP may be provided in a bonded structure of the substrate 110 and the opposing substrate 120′. Therefore, in the case of the transparent display apparatus according to FIG. 5, the main touch electrode MTE and the auxiliary touch electrode STE may be provided in an in-cell structure arranged between the substrate 110 and the opposing substrate 120′. In addition, the transparent display apparatus 100 according to FIG. 5 can be provided with a structure in which the substrate 110 and the opposing substrate 120′ are manufactured separately and then bonded together, so that an area (or size) of each of the substrate 110 and the opposing substrate 120′ can be increased, so that it can be used as a large-area transparent display apparatus. Referring to FIG. 5, in a transparent display apparatus 100 according to the second embodiment of the present disclosure, the transparent display panel TDP may be formed by bonding a substrate 110 and an opposing substrate 120′, and a plurality of sealing members SLG may be arranged on each side of the substrate 110 and the opposing substrate 120′. The plurality of sealing members SLG are intended to protect the plurality of side contact electrodes SCE (shown in FIG. 10) from external impact and/or moisture penetration. The plurality of side contact electrodes SCE according to one example are for transmitting a touch signal sensed on the opposing substrate 120′ to the touch driver 210 provided on the substrate 110.

Referring to FIG. 6, in the transparent display apparatus 100 according to the second embodiment of the present disclosure, a substrate 110 may include the display area DA provided with the plurality of pixels P, and a non-display area NDA. The opposing substrate 120′ may include a touch area TUA, and a main touch electrode MTE may be arranged in the touch area TUA. As shown in FIG. 6, the touch area TUA of the opposing substrate 120′ can be formed to correspond to the display area DA provided on the substrate 110. According to one example, the main touch electrode MTE may include a plurality of first main touch electrodes MTX and a plurality of second main touch electrodes MRX.

Since the transparent display apparatus 100 according to the second embodiment of the present disclosure has a large-area transparent display panel TDP, an overall size (or area) of the transparent display panel TDP can be larger than that of the transparent display apparatus according to FIG. 1. Accordingly, the opposing substrate 120′ may be provided with a greater number of touch areas, the first main touch electrodes MTX, and the second main touch electrodes MRX than the transparent display apparatus according to FIG. 1.

For example, the touch area TUA may include six first touch areas TUA spaced apart in the second direction (X-axis direction). Accordingly, each of the plurality of first main touch electrodes MTX in each of the six first touch areas can be connected to a plurality of upper pads UPAD provided on the opposing substrate 120′ through the first touch driving electrode line TXL1 to the sixth touch driving electrode line TXL6.

In addition, the second touch area TUA2 may be provided with two 1a touch receiving electrodes RX1a and 1b touch receiving electrodes RX1b spaced apart from each other in the second direction (X-axis direction). The 1a touch receiving electrode RX1a can be connected to the upper pad UPAD via the 1a touch receiving electrode line RXL1a. The 1b touch receiving electrode RX1b can be connected to the upper pad UPAD via the 1b touch receiving electrode line RXL1b.

An another second touch area TUA2′ spaced apart from the second touch area TUA2 in the first direction (Y-axis direction) may be provided with two 2a touch receiving electrodes RX2a and 2b touch receiving electrodes RX2b spaced apart from each other in the second direction (X-axis direction). The 2a touch receiving electrode RX2a can be connected to the upper pad UPAD via the 2a touch receiving electrode line RXL2a. The 2b touch receiving electrode RX2b can be connected to the upper pad UPAD via the 2b touch receiving electrode line RXL2b.

Each of the plurality of upper pads UPAD provided in the non-display area NDA of the opposing substrate 120′ can be electrically connected to each of the plurality of lower pads DPAD provided on the substrate 110 through each of the plurality of side contact electrodes SCE. The plurality of lower pads DPAD provided on the substrate 110 can be connected to the touch driver 210 through a plurality of lines. Accordingly, a touch signal sensed through the main touch electrode MTE and the auxiliary touch electrode STE of the opposing substrate 120′ can be transmitted (or transferred) to the touch driver 210 provided on the substrate 110 through the plurality of side contact electrodes SCE.

The transparent display apparatus 100 according to the second embodiment of the present disclosure has the side contact electrodes SCE disposed on each side of the substrate 110 (or the lower substrate) and the opposing substrate 120′ (or the upper substrate), so that the touch electrodes of the opposing substrate 120′ (or an upper substrate) can be connected to the touch driver 210 of the substrate 110 (or the lower substrate) through the side contact electrodes SCE, and thus a large area can be implemented while minimizing bezel increase.

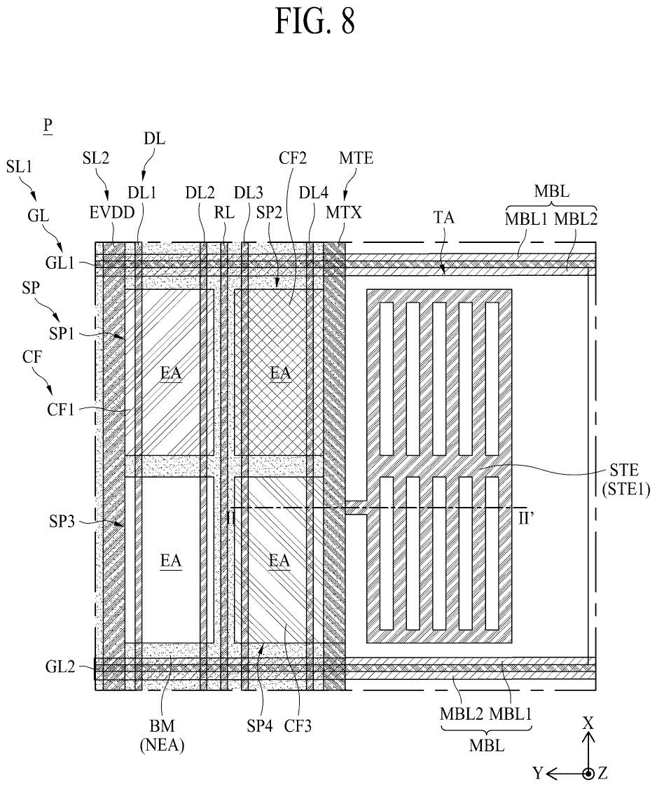

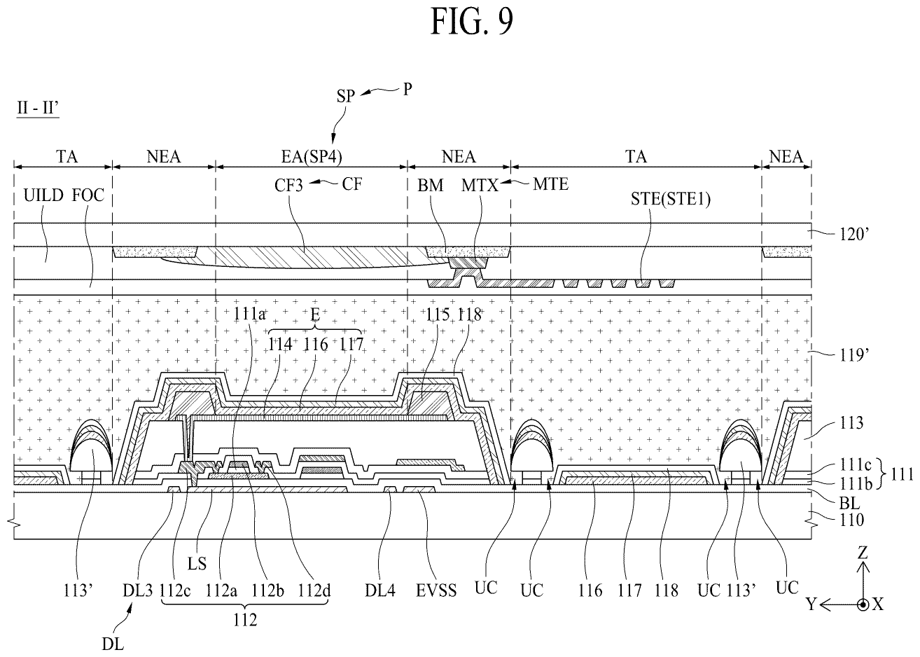

Hereinafter, the plurality of pixel P structures of the transparent display apparatus 100 according to the second embodiment of the present disclosure will be specifically described with reference to FIGS. 8 and 9.

FIG. 8 is a schematic plan view showing one pixel of a transparent display apparatus according to the second embodiment of the present disclosure, and FIG. 9 is a cross-sectional view showing one example of II-II′ of FIG. 8.

In the transparent display apparatus 100 according to the second embodiment of the present disclosure, the transparent display panel TDP may include the opposing substrate 120′ and the substrate 110 bonded to the opposing substrate 120′. According to one example, the substrate 110 may include the display area DA and the non-display area NDA. The display area DA may be provided with a plurality of pixels P, each of which includes a transmissive area TA and a plurality of subpixels SP. According to one example, the display area DA may include the light emission area EA, the non-light emission area NEA, and the transmissive area TA.

The display area DA according to one example may include gate lines, data lines, pixel driving power lines EVDD, and the plurality of pixels P. Each of the plurality of pixels P may include a plurality of subpixels SP that may be defined by the gate lines GL and the data lines DL.

Referring to FIG. 8, at least four subpixels SP that are arranged adjacently and are configured to emit different colors can form one pixel P (or unit pixel). One pixel P may include, but is not limited to, a red subpixel, a white subpixel, a blue subpixel, and a green subpixel. One pixel P may be composed of three subpixels SP arranged adjacently and configured to emit different colors. For example, one pixel P may include a red subpixel, a green subpixel, and a blue subpixel.

Each of the plurality of subpixels SP may include a thin film transistor and a light emitting element layer E connected to the thin film transistor. Each of the plurality of subpixels may include a light emitting layer (or an organic light emitting layer) interposed between the pixel electrode and the reflective electrode.

The light-emitting layer arranged in each of the plurality of subpixels SP can commonly emit white light. Since the light-emitting layers of each of the plurality of subpixels SP commonly emit white light, each of the red subpixel, the green subpixel, and the blue subpixel may include a color filter CF (or a wavelength conversion member CF) that converts the white light into light of a different color. In this case, the white subpixel may not have a color filter.

In the transparent display apparatus 100 according to the second embodiment of the present disclosure, an area provided with the green color filter may be a green subpixel or a first subpixel, an area provided with the blue color filter may be a blue subpixel or a second subpixel, an area not provided with the color filter may be a white subpixel or a third subpixel, and an area provided with the red color filter may be a red subpixel or a fourth subpixel. When one unit pixel P of the transparent display apparatus 100 according to one embodiment of the present disclosure includes four subpixels, the four subpixels may mean the green subpixel (or the first subpixel SP1), the blue subpixel (or the second subpixel SP2), the white subpixel (or the third subpixel SP3), and the red subpixel (or the fourth subpixel SP4).

As shown in FIG. 8, the plurality of subpixels SP may include a first subpixel SP1 and a second subpixel SP2 that are arranged sequentially in the first direction (Y-axis direction) and are equipped to emit different colors, and a third subpixel SP3 and a fourth subpixel SP4 that are arranged sequentially in the first direction (Y-axis direction) and are equipped to emit different colors from the first subpixel SP1 and the second subpixel SP2. The third subpixel SP3 and the fourth subpixel SP4 can be arranged adjacent to the first subpixel SP1 and the second subpixel SP2 in the second direction (X-axis direction). Accordingly, the transparent display apparatus 100 according to the second embodiment of the present disclosure may be provided with a quad structure in which the green sub-pixel SP1, the blue sub-pixel SP2, the red sub-pixel SP4, and the white sub-pixel SP are arranged adjacently in a clockwise direction. However, it is not necessarily limited to this, and the arrangement order of the first subpixel SP1, the second subpixel SP2, the third subpixel SP3, and the fourth subpixel SP4 may be changed. Hereinafter, one example in which a plurality of subpixels SP are provided with a structure as in FIG. 8 will be described.

As shown in FIG. 8, the transmissive area TA may be arranged adjacent to a right side of each of the second subpixel SP2 and the fourth subpixel SP4. An auxiliary touch electrode STE may be arranged in the transmissive area TA. The auxiliary touch electrode STE can be connected to the main touch electrode MTE. According to one example, the main touch electrode MTE can be arranged to overlap each of the black matrix BM between the second subpixel SP2 and the transmissive area TA and the black matrix BM between the fourth subpixel SP4 and the transmissive area TA. For example, as shown in FIG. 8, the main touch electrode MTE can be arranged to extend in the second direction (X-axis direction) between the second subpixel SP2 and the transmissive area TA.

Each of the subpixels SP supplies a predetermined current to the organic light-emitting element according to the data voltage of the data line when a gate signal is input from the gate line using a thin film transistor. As a result, the light-emitting layer of each of the subpixels can emit light with a predetermined brightness according to a predetermined current.

Each of the first to fourth subpixels SP1 to SP4 may include the light emission area EA and a circuit area. The light emission areas EA of each of the first to fourth subpixels SP1 to SP4 may have the same size (or area) or different sizes (or areas).

Meanwhile, two data lines DL (e.g., a second data line DL2 and a third data line DL3) extending along the first direction (X-axis direction) may be arranged parallel to each other between the first sub-pixel SP1 and the second sub-pixel SP2, and between the third sub-pixel SP3 and the fourth sub-pixel SP4. A pixel power line EVDD and a first data line DL1 extending along the second direction (X-axis direction) may be arranged on a left side of each of the first sub-pixel SP1 and the third sub-pixel SP3.

The gate line GL can be arranged on an upper side and a lower side of each of the plurality of subpixels SP and the transmissive area TA. For example, the gate line GL may include a first gate line GL1 and a second gate line GL2. The first gate line GL1 may be arranged to extend along the first direction (Y-axis direction) above each of the first subpixel SP1, the second subpixel SP2, and the transmissive area TA. The second gate line GL2 may be arranged to extend along the first direction (Y-axis direction) below each of the third sub-pixel SP3, the fourth sub-pixel SP4, and the transmissive area TA.

As shown in FIG. 8, a main bridge line MBL connected to the main touch electrode MTE can be arranged along each of the first gate line GL1 and the second gate line GL2. The main bridge line MBL according to one example may include a first main bridge line MBL1 and a second main bridge line MBL2. Although FIG. 8 illustrates that two main bridge lines are arranged along each of the first gate line GL1 and the second gate line GL2, the present invention is not limited thereto, and if the touch signal of the main touch electrode MTE can be transmitted to the touch driver, one main bridge line may be arranged along each of the first gate line GL1 and the second gate line GL2. However, when two main bridge lines are arranged along each of the first gate line GL1 and the second gate line GL2, the resistance can be reduced compared to when one main bridge line is arranged along each of the first gate line GL1 and the second gate line GL2, so that touch signal detection can be improved. In FIG. 8, only the main bridge line MBL is illustrated as extending in the first direction (Y-axis direction) on each of the upper and lower sides of the transmissive area TA, but the black matrix may be formed to overlap with the main bridge line MBL on each of the upper and lower sides of the transmissive area TA. In this case, the black matrix can reduce external light reflection by the main bridge line MBL.

Meanwhile, a reference line RL extending along the first direction (X-axis direction) may be arranged between the second data line DL2 and the third data line DL3. The reference line RL can be used as a sensing line for externally sensing changes in the characteristics of a driving thin film transistor arranged in a circuit area and/or changes in the characteristics of a light-emitting element layer when the pixel P is in a sensing driving mode. Data lines DL according to one example are for supplying data signals to each of the plurality of subpixels so that each of the plurality of subpixels can be driven. For example, the first data line DL1 is for driving the first subpixel SP1, the second data line DL2 is for driving the second subpixel SP2, the third data line DL3 is for driving the third subpixel SP3, and the fourth data line (DL4) is for driving the fourth subpixel SP4.

Hereinafter, referring to FIG. 4, a structure of each of the plurality of subpixels SP will be described in detail.

Referring to FIG. 9, in the transparent display apparatus 100 according to the second embodiment of the present disclosure, each of the subpixels SP may include a circuit element layer 111 provided on an upper surface of a buffer layer BL, including a gate insulating layer 111a, an interlayer insulating layer 111b and a passivation layer 111c, an overcoat layer 113 provided on the circuit element layer 111, a pixel electrode 114 provided on the overcoat layer 113, a bank 115, an organic light emitting layer 116, a cathode electrode 117, an encap layer 118, and an encapsulation layer 119.

The cross-sectional structure of the subpixel SP of the transparent display apparatus 100 according to the second embodiment of the present disclosure is similar to the cross-sectional structure of the subpixel SP of the transparent display apparatus according to one embodiment of the present disclosure, and therefore, the same drawing reference numerals are given to the same configurations, and only different configurations will be described below.

As shown in FIG. 9, the pixel power line EVDD, the data line DL, and the common power line EVSS for supplying a common voltage to each of a plurality of subpixels SP may be arranged between the buffer layer BL and the substrate 110. In addition, a light-shielding layer LS may be placed between the buffer layer BL and the substrate 110 (or the active layer 112a). Accordingly, the light incident toward the active layer 112a through the substrate 110 is blocked by the light-shielding layer LS, so that the threshold voltage change of the transistor due to external light can be minimized.

The organic light-emitting layer 116 can be formed as a common layer provided on a plurality of subpixels SP and a bank 115. In this case, the organic light-emitting layer 116 may be provided in a tandem structure in which a plurality of light-emitting layers, for example, a yellow-green light-emitting layer and a blue light-emitting layer, are laminated, and when an electric field is formed between the pixel electrode 114 and the cathode electrode 117, white light can be emitted. Accordingly, the transparent display apparatus 100 according to the second embodiment of the present disclosure may be provided such that the organic light-emitting layer 116 disposed in each of the plurality of subpixels SP emits the same color.

For example, the organic light emitting layer 116 may include a plurality of stacks which emit lights of different colors. The organic light emitting layer 116 according to one embodiment may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the transparent display apparatus 100 according to the second embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

A color filter CF matching the color of the corresponding subpixel SP can be formed on the opposing substrate 120′. For example, the green subpixel SP1 may be equipped with a green color filter CF1, the blue subpixel SP2 may be equipped with a blue color filter CF2, and the red subpixel SP4 may be equipped with a red color filter CF3. The white subpixel may not be provided with a color filter because the organic light-emitting layer 116 emits white light.

The cathode electrode 117 is formed on the organic light-emitting layer 116. The cathode electrode 117 may be a common layer formed commonly on the subpixels SP. The cathode electrode 117 can be formed of a transparent metal material TCO (or Transparent Conductive Material) that can transmit light, such as ITO or IZO, or a semi-transmissive conductive material, such as magnesium Mg, silver Ag, or an alloy of magnesium Mg and silver Ag.

An encap layer 118 is formed on the cathode electrode 117. The encap layer 118 serves to prevent oxygen or moisture from penetrating into the organic light-emitting layer 116 and the cathode electrode 117. To this end, the encap layer 118 may be arranged as a common layer in the light emission area EA, the non-light emission area NEA, and the transmissive area TA. According to one example, the encap layer 118 may include an inorganic film and/or an organic film.

An encapsulation layer 119 is formed on the encap layer 118. The encapsulation layer 119 serves to prevent oxygen or moisture from penetrating into the organic light-emitting layer 116 and the cathode electrode 117. For this purpose, the encapsulating layer 119 may include at least one organic film and at least one inorganic film.

In the transparent display apparatus 100 according to the second embodiment of the present disclosure, the encapsulation layer 119 may be arranged not only in the display area DA but also in the non-display area NDA. According to one example, the encapsulation layer 119 may be arranged between the cathode electrode 117 (and/or the encap layer 118) and the opposing substrate 120′.

Since the transparent display apparatus 100 according to the second embodiment of the present disclosure can have a transparent display panel formed by a bonding structure of the substrate 110 and the opposing substrate 120′, the encapsulation layer 119 can be formed of a transparent adhesive material. In this case, since an encapsulation layer of the transparent display apparatus 100 according to the second embodiment of the present disclosure is a different material from the encapsulation layer 119 of the transparent display apparatus according to one embodiment of the present disclosure, the encapsulation layer may be indicated by the drawing symbol 119′ as in FIG. 9. The adhesive strength between the substrate 110 and the opposing substrate 120′ can be improved due to the encapsulation layer 119′ made of the transparent adhesive material, and thus the reliability of the transparent display apparatus 100 can be improved.

Meanwhile, since the transparent display apparatus 100 according to the second embodiment of the present disclosure can form touch electrodes on the opposing substrate 120′ (or upper substrate 120′) by utilizing the process line of the substrate 110 (or lower substrate 110), production energy can be reduced through process optimization.

Referring again to FIG. 9, the transparent display apparatus 100 according to the second embodiment of the present disclosure may include an undercut portion UC in which the overcoat layer 113 and the circuit element layer 111 (or inorganic film layer) are partially removed.

According to one example, the undercut portion UC may be formed by partially removing each of the interlayer insulating layer 111b and the passivation layer 111c. As shown in FIG. 9, the undercut portion UC may be formed in the transmissive area TA. That is, the transmissive area TA may include the undercut portion UC.

The undercut portion UC is intended to disconnect the organic light-emitting layer 116 provided in the transmissive area TA. In the transparent display apparatus 100 according to one embodiment of the present disclosure, the organic light-emitting layer 116, the cathode electrode 117, and the encap layer 118 are formed after the undercut portion UC is formed, so that the organic light-emitting layer 116 can be disconnected by the undercut portion UC. Therefore, the transparent display apparatus 100 according to the second embodiment of the present disclosure can prevent moisture penetration through the organic light-emitting layer 116.

The undercut portion UC can be formed on both sides of the overcoat layer 113′ disposed in the transmissive area TA. The overcoat layer 113′ disposed in the transmissive area TA is disposed in an island shape spaced apart from the overcoat layer 113 disposed in the light emission area EA, and therefore can be expressed in terms of an island OC or a first overcoat layer. In contrast, the overcoat layer 113 arranged to overlap the light emission area EA (and/or the non-light emission area NEA) is arranged to cover the thin film transistor 112, and therefore may be expressed in terms of a capping OC or a second overcoat layer.

Referring to FIG. 9, in the transparent display apparatus 100 according to the second embodiment of the present disclosure, the organic light-emitting layer 116 may be disconnected at the undercut portion UC. Additionally, the cathode electrode 117 and the encap layer 118 may also be disconnected at the undercut portion UC. Accordingly, as illustrated in FIG. 9, the first overcoat layer 113′, the organic light-emitting layer 116, the cathode electrode 117, and the encap layer 118 disposed on the first overcoat layer 113′ can be disposed in an island shape. Therefore, on both sides of the first overcoat layer 113′, the encapsulation layer 119′ can be placed up to the undercut portion UC. However, it is not necessarily limited to this, and the encapsulation layer 119′ may be partially formed on only one side of the first overcoat layer 113′. The encapsulating layer 119′ may include a getter that absorbs moisture and/or oxygen. Accordingly, in the transparent display apparatus 100 according to the second embodiment of the present disclosure, since the encapsulation layer 119′ including the getter is arranged up to the undercut portion UC, moisture permeation prevention can be maximized.

The main touch electrode MTE, the auxiliary touch electrode STE, the color filter CF, and the black matrix BM can be placed between the encapsulation layer 119′ and the opposing substrate 120′. According to one example, the color filter CF may be arranged to correspond to each of the plurality of subpixels SP (or the plurality of light emission areas EA) on an opposing substrate 120′.

As described above, the white sub-pixel, i.e., the third sub-pixel SP3, may not be provided with the color filter because the organic light-emitting layer 116 emits white light. On the other hand, the fourth sub-pixel SP4, which is the red sub-pixel, may be provided with the red color filter CF3 (or the third color filter CF3) between the encapsulation layer 119 and the opposing substrate 120′.

As shown in FIG. 9, the black matrix BM can be placed at an edge of the color filter CF. Therefore, the black matrix BM can prevent color mixing between subpixels SP. The black matrix BM is made of a black material and can be placed in a non-light emission area NEA. According to one example, the black matrix BM is formed on the opposing substrate 120′ so as to overlap at least partly with the bank 115, thereby reducing a cell gap between the organic light-emitting layer 116 and the opposing substrate 120′, thereby preventing color mixing between subpixels.

Meanwhile, in the transparent display apparatus 100 according to the second embodiment of the present disclosure, the main touch electrode MTE may be placed under the black matrix BM. For example, as shown in FIG. 9, the first main touch electrode MTX may be placed so as to be in contact with a lower surface of the black matrix BM. Due to this, the main touch electrode MTE may not overlap (or interfere with) the transmissive area TA. Accordingly, the transparent display apparatus 100 according to the second embodiment of the present disclosure is provided such that the main touch electrode MTE is arranged below the black matrix BM, so that the touch electrode can be provided without interference with the transmissive area TA, and thus can be implemented as a touch transparent display apparatus in which a decrease in transmittance is minimized or prevented. In addition, the transparent display apparatus 100 according to the second embodiment of the present disclosure may not have its light efficiency reduced because the main touch electrode MTE is positioned below the black matrix BM so as not to interfere with the light emission area EA.

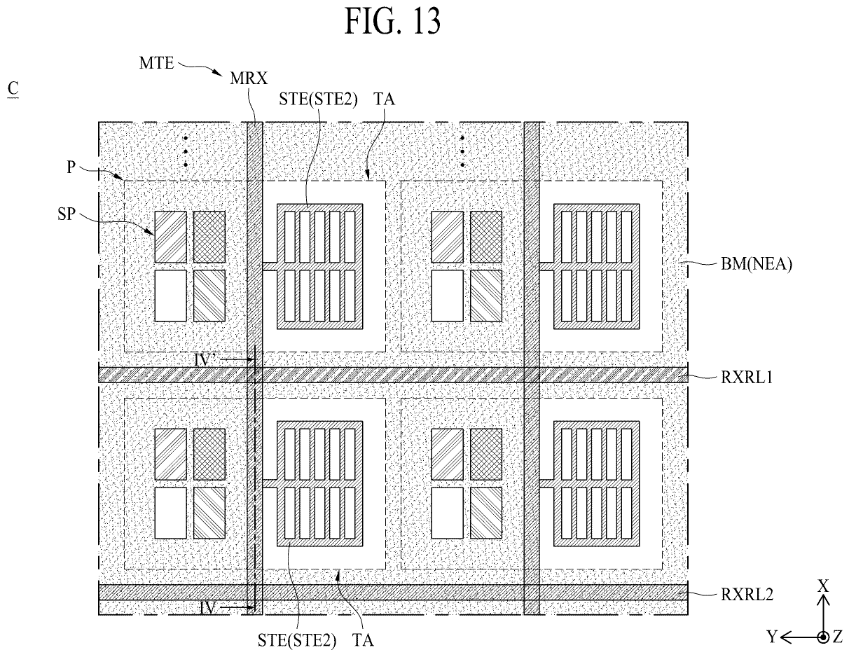

The auxiliary touch electrode STE can partially contact a lower surface of the main touch electrode MTE. For example, as shown in FIG. 9, a part of the first auxiliary touch electrode STE1 may be in contact with the lower surface of the main touch electrode MTE in the non-light emission area NEA, and a remainder of the first auxiliary touch electrode STE1 may be extended in the first direction (Y-axis direction) and placed in the transmissive area TA. Accordingly, the first auxiliary touch electrode STE1 can be electrically connected to the main touch electrode MTE and can be mostly placed in the transmissive area TA. The first auxiliary touch electrode STE1 arranged in the transmissive area TA can sense a user's touch and transmit the sensed signal to the main touch electrode MTE. This structure can be equally applied to the second auxiliary touch electrode STE2 (shown in FIG. 13).

An upper insulating layer UILD may be placed between the auxiliary touch electrode STE and the opposing substrate 120′. The upper insulating layer UILD is intended to level the uneven structure formed by the color filter CF, black matrix BM, and main touch electrode MTE. Accordingly, the upper insulating layer UILD can be formed on the front (or back) of the opposing substrate 120′ to cover the color filter CF, the black matrix BM, and the main touch electrode MTE. Since the upper insulating layer UILD is provided to cover the color filter CF, the black matrix BM, and the main touch electrode MTE, a front side (or a back side) of the upper insulating layer UILD can be provided flat, and thus the auxiliary touch electrode STE can be easily formed on the front side (or the back side) of the upper insulating layer UILD.

An upper organic film FOC covering the auxiliary touch electrode STE may be placed between the upper insulating layer UILD and the encapsulation layer 119′. As described above, the transparent display panel of the transparent display apparatus 100 according to the second embodiment of the present disclosure may be formed by bonding the substrate 110 and the opposing substrate 120′ after each of them is manufactured. Therefore, if the bonding process is performed while the auxiliary touch electrode STE is exposed to the outside, the auxiliary touch electrode STE may be damaged by foreign substances, which may result in a defect. Therefore, the transparent display apparatus 100 according to the second embodiment of the present disclosure is provided with the upper organic film FOC covering the auxiliary touch electrode STE, thereby preventing the auxiliary touch electrode STE from being exposed during the bonding process, thereby improving reliability.

Meanwhile, as shown in FIG. 9, the transparent display apparatus 100 according to the second embodiment of the present disclosure may have a structural feature in which the auxiliary touch electrode STE is positioned below the main touch electrode MTE, thereby positioning the auxiliary touch electrode STE closer to the substrate 110 than the main touch electrode MTE.

Referring to FIG. 9, in the transparent display apparatus 100 according to the second embodiment of the present disclosure, the cathode electrode 117 can be placed in the light emission area EA and the transmissive area TA. As described above, since the cathode electrode 117 is formed after the undercut portion UC is formed, the cathode electrode 117 can be disconnected by the undercut portion UC. Accordingly, as shown in FIG. 9, the cathode electrode 117 arranged in the transmissive area TA may be disconnected from the cathode electrode 117 arranged in the light emission area EA. Therefore, the cathode electrode 117 arranged in the transmissive area TA may be a floating electrode to which no power or voltage is applied.

Meanwhile, the cathode electrode 117 (or the floating electrode 117) placed in the transmissive area TA may be placed to partially overlap with the auxiliary touch electrode STE (or the auxiliary touch electrode STE placed in the transmissive area TA). Since no power or voltage is applied to the cathode electrode 117 placed in the transmissive area TA, the sensing load of the auxiliary touch electrode STE may be minimized or no load may be generated. Therefore, the transparent display apparatus 100 according to the second embodiment of the present disclosure can have improved touch sensitivity of the auxiliary touch electrode STE. In addition, the transparent display apparatus 100 according to the second embodiment of the present disclosure can be implemented as a transparent display apparatus capable of double-sided touch since the load of the auxiliary touch electrode STE and the floating electrode is minimized or no load is generated. The transparent display apparatus 100 according to the second embodiment of the present disclosure can sense touch in a mutual type using the plurality of auxiliary touch electrodes STE, and thus can be implemented as the transparent display apparatus capable of double-sided touch.

For example, in the transparent display apparatus 100 according to the second embodiment of the present disclosure, mutual touch sensing causes an electric field generated from the first auxiliary touch electrode STE1 to enter the second auxiliary touch electrode STE2 positioned adjacent to the first auxiliary touch electrode STE1. Here, if there is no change in the mutual capacitance between the first auxiliary touch electrode STE1 and the second auxiliary touch electrode STE2, it is determined that no touch has occurred, and if there is a change in the mutual capacitance between the first auxiliary touch electrode STE1 and the second auxiliary touch electrode STE2 (for example, if the mutual capacitance decreases), it is determined that a touch has occurred, so that touch sensing can be performed.

For example, when a touch is generated by a user's finger on the opposing substrate 120′ side, a portion of the electric field generated from the first auxiliary touch electrode STE1 may enter the user's finger. Due to this, the transparent display apparatus 100 according to the second embodiment of the present disclosure can sense touch because the mutual capacitance between the first auxiliary touch electrode STE1 and the second auxiliary touch electrode STE2 is reduced.

As shown in FIG. 7, in the transparent display apparatus 100 according to the second embodiment of the present disclosure, the first main touch electrode MTX is arranged adjacent to the second main touch electrode MRX in the first direction (Y-axis direction), so that the auxiliary touch electrode STE (or the first auxiliary touch electrode STE1) connected to the first main touch electrode MTX and the auxiliary touch electrode STE (or the second auxiliary touch electrode STE2) connected to the second main touch electrode MRX can be arranged adjacent to each other in the first direction (Y-axis direction). Accordingly, the transparent display apparatus 100 according to the second embodiment of the present disclosure can sense a touch because the mutual capacitance between the first auxiliary touch electrode STE1 and the second auxiliary touch electrode STE2 can be changed when a touch occurs on the opposite substrate 120′.

Meanwhile, the transparent display apparatus 100 according to the second embodiment of the present disclosure can also sense touch on the substrate 110 placed below the opposing substrate 120′. As shown in FIG. 9, the transparent display apparatus 100 according to the second embodiment of the present disclosure is provided with the cathode electrode 117 overlapping with the auxiliary electrode touch electrode STE (or the first auxiliary touch electrode STE1) as the floating electrode, so that the load of the auxiliary touch electrode STE and the floating electrode can be minimized or not generated. Accordingly, the transparent display apparatus 100 according to the second embodiment of the present disclosure can sense a touch because the mutual capacitance between the first auxiliary touch electrode STE1 and the second auxiliary touch electrode STE2 can be changed even when a touch occurs on the substrate 110.

As a result, the transparent display apparatus 100 according to the second embodiment of the present disclosure can sense both a touch (or upper touch) generated on the opposing substrate 120′ and a touch (or lower touch) generated on the substrate 110, since the load of the auxiliary touch electrode STE and the floating electrode is minimized or no load is generated, and thus can be implemented as the transparent display apparatus capable of double-sided touch.

Meanwhile, as shown in FIG. 9, the transparent display apparatus 100 according to the second embodiment of the present disclosure does not have the interlayer insulating layer 111b and the passivation layer 111c in the transmissive area TA, so that the transmittance of the transmissive area TA can be improved compared to a case where the interlayer insulating layer 111b and the passivation layer 111c are provided in the transmissive area.

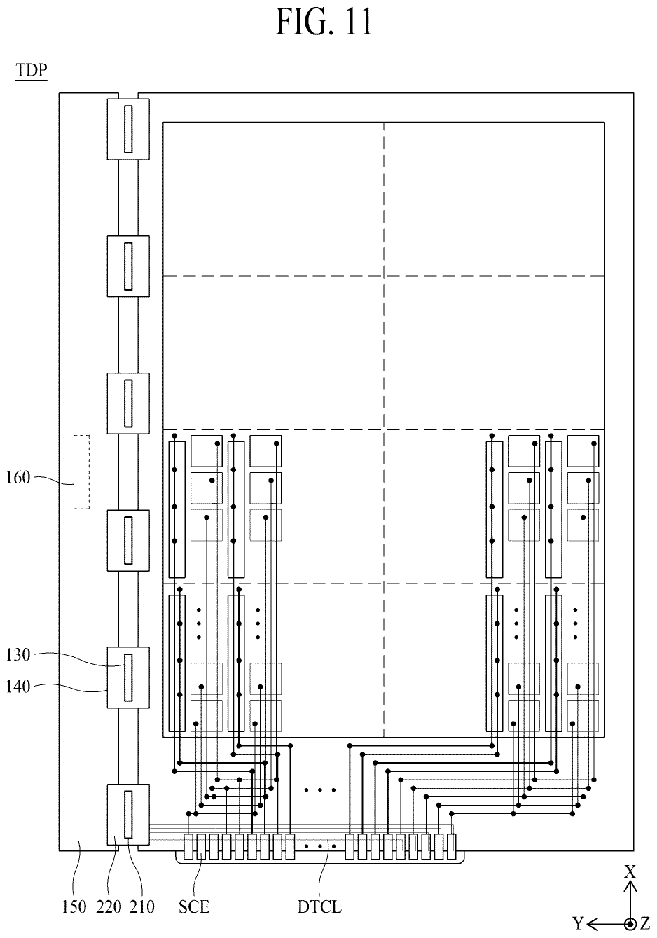

FIG. 10 is a cross-sectional view showing one example of III-III′ of FIG. 5, and FIG. 11 is a schematic illustration showing a transparent display panel including a touch electrode of a transparent display apparatus according to the second embodiment of the present disclosure.

Referring to FIG. 6 and FIG. 10, the transparent display apparatus 100 according to the second embodiment of the present disclosure may further include a plurality of upper pads UPAD, a plurality of lower pads DPAD, and a side contact electrode SCE.

According to one example, the upper pad UPAD can be connected to the touch driving electrode line TXL. Since the touch driving electrode line TXL is connected to the main touch electrode MTE, the touch driving electrode line TXL can transmit the sensing signal of the main touch electrode MTE to the upper pad UPAD. The upper pad UPAD according to one example may be provided at an end of the opposing substrate 120′. Therefore, as shown in FIG. 10, the upper pad UPAD can partially contact an upper surface of a dam DAM. According to one example, the dam DAM may be in contact with each side of the circuit element layer 111, the overcoat layer 113, the light-emitting element layer E, the encapsulation layer 119′, and the upper organic film FOC provided on the substrate 110. Accordingly, the dam DAM can prevent at least one of the circuit element layer 111, the overcoat layer 113, the light emitting element layer E, the encapsulation layer 119′, and the upper organic film FOC from flowing out or protruding to the outside of the substrate 110 and/or the opposing substrate 120′.

According to one example, the lower pad DPAD is provided on the substrate 110 and may be positioned to face the upper pad UPAD. For example, the lower pad DPAD may be positioned at an end of the substrate 110 to face the upper pad UPAD in the third direction (Z-axis direction). And, the lower pad DPAD can partially contact the lower surface of the dam DAM. Each of the plurality of lower pads DPAD can be connected to the touch drive 210 through a plurality of lower touch connection lines DTCL (shown in FIG. 11).

According to one example, the side contact electrode SCE is provided to transmit a touch signal sensed by the touch electrode on the opposing substrate 120′ to the touch driver 210 provided on the substrate 110. As shown in FIG. 10, the side contact electrode SCE may be provided to cover a lower surface and a side surface (or a right surface) of the upper pad UPAD that is not covered by the dam DAM, and to cover an upper surface and a side surface (or a right surface) of the lower pad DPAD that is not covered by the dam DAM. Therefore, the side contact electrode SCE can electrically connect the upper pad UPAD and the lower pad DPAD. Therefore, a touch signal sensed (or detected) through the main touch electrode MTE and/or the auxiliary touch electrode STE of the opposing substrate 120′ can be transmitted to the touch driver 210 through the upper pad UPAD, the side contact electrode SCE, and the lower pad DPAD.

As a result, the transparent display apparatus 100 according to the second embodiment of the present disclosure can transmit a touch signal detected by the main touch electrode MTE and/or the auxiliary touch electrode STE provided on the opposing substrate 120′ to the touch driver 210 on the substrate 110 through the side contact electrode SCE, even if the substrate 110 and the opposing substrate 120′ are manufactured and bonded separately. Therefore, the transparent display apparatus 100 according to the second embodiment of the present disclosure can be implemented as a large-area transparent display apparatus equipped with the touch electrode.

Meanwhile, the side contact electrode SCE can be printed on each side of the substrate 110 and the opposing substrate 120′ using a printing method after the substrate 110 and the opposing substrate 120′ are bonded. Accordingly, the transparent display apparatus 100 according to the second embodiment of the present disclosure may have a structural feature in which the side contact electrode SCE covers at least a portion of a side surface of the substrate 110 and at least a portion of a side surface of the opposing substrate 120′.

Additionally, the transparent display apparatus 100 according to the second embodiment of the present disclosure may further include a sealing portion SLP. The sealing portion SLP is to prevent the side contact electrode SCE from being exposed to the outside. When the side contact electrode is exposed to the outside, the side contact electrode made of a metal material may be oxidized by external air or moisture or damaged by external impact. Accordingly, the sealing portion SLP can be brought into contact with each side of the substrate 110 and the opposing substrate 120′ while covering the side contact electrode SCE. As a result, the side contact electrode SCE can be prevented from oxidation and protected from impact by being sealed by the sealing portion SLP.

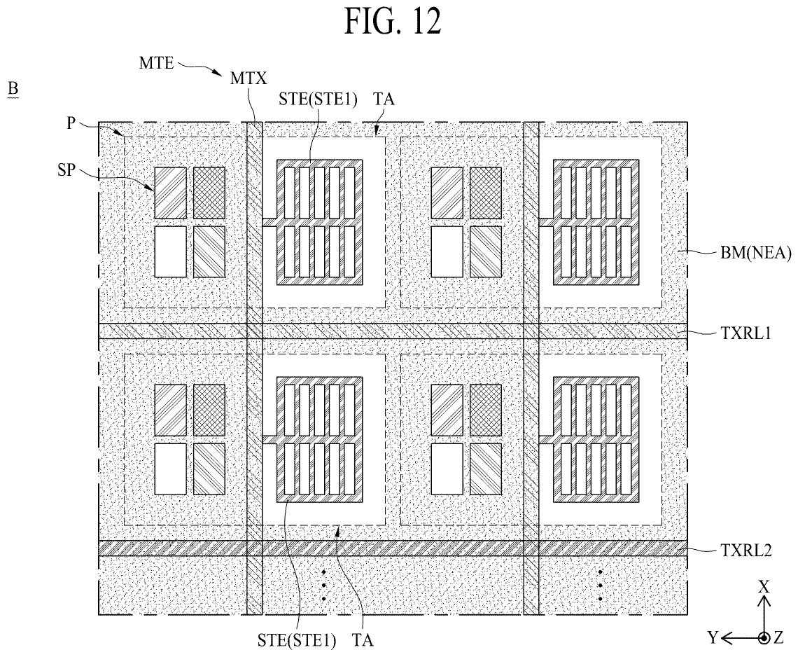

FIG. 12 is an enlarged view of part B of FIG. 7, and FIG. 13 is an enlarged view of part C of FIG. 7.

Referring to FIG. 12, in the transparent display apparatus 100 according to the second embodiment of the present disclosure, one first main touch electrode MTX among a plurality of first main touch electrodes MTX can be connected to at least two or more first auxiliary touch electrodes STE1. For example, as illustrated in FIG. 12, the first main touch electrode MTX extending in the second direction (X-axis direction) may be connected to the first auxiliary touch electrode STE1 provided in the transmissive area TA of each of the plurality of pixels P. Here, the plurality of pixels P may mean pixels P arranged adjacently in the second direction (X-axis direction). Accordingly, one first main touch electrode MTX can transmit a touch signal sensed by each of the two first auxiliary touch electrodes STE1 to the upper pad UPAD through the touch line and the touch driving electrode line.

Meanwhile, the first main touch electrode MTX may be connected to a first touch routing line TXRL1. For example, the first main touch electrode MTX extended in the second direction (X-axis direction) may be arranged between the plurality of pixels P and may be connected to the first touch routing line TXRL1 extended in the first direction (Y-axis direction). As shown in FIG. 12, an another first touch routing line TXRL2 may be arranged in parallel below the first touch routing line TXRL1 with the pixel P therebetween. The another first touch routing line TXRL2 can be connected to a first main touch electrode MTX in an another pixel spaced apart in the first direction (Y-axis direction). Accordingly, the first touch routing line TXRL1 and the another first touch routing line TXRL2 can transmit touch signals sensed from pixels P (or first auxiliary touch electrodes STE1) arranged at different locations, respectively.

The first touch routing line TXRL1 and the another first touch routing line TXRL2 can be arranged in one touch area. Therefore, each of the first touch routing line TXRL1 and the another first touch routing line TXRL2 can be connected in the non-display area NDA through the touch line and the touch driving electrode line. For example, assuming that the first touch routing line TXRL1 and the another first touch routing line TXRL2 are arranged on a 1a sub-touch electrode driving electrode STX1a of FIG. 7, each of the first touch routing line TXRL1 and the another first touch routing line TXRL2 can be connected to each of the plurality of 1a touch lines STXL1a, and the plurality of 1a touch lines STXL1a can be connected to the first touch driving electrode line TXL1 in the non-display area NDA. Therefore, the first touch routing line TXRL1 and the another first touch routing line TXRL2 can be electrically connected in the non-display area NDA.

Referring to FIG. 13, in the transparent display apparatus 100 according to the second embodiment of the present disclosure, one second main touch electrode MRX among a plurality of second main touch electrodes MRX can be connected to at least two or more second auxiliary touch electrodes STE2. For example, as illustrated in FIG. 13, the second main touch electrode MRX extending in the second direction (X-axis direction) may be connected to the second auxiliary touch electrode STE2 provided in the transmissive area TA of each of the plurality of pixels P. Here, the plurality of pixels P may mean pixels P arranged adjacently in the second direction (X-axis direction). Accordingly, one second main touch electrode MRX can transmit a touch signal sensed from each of two second auxiliary touch electrodes STE2 to the upper pad UPAD through the touch receiving electrode line RXL.

Meanwhile, the second main touch electrode MRX may be connected to the second touch routing line RXRL1. For example, the second main touch electrode MRX extended in the second direction (X-axis direction) may be connected to an another second touch routing line RXRL2 extended in the first direction (Y-axis direction). As shown in FIG. 13, the second touch routing line RXRL1 may be arranged in parallel with the pixel P interposed therebetween on the another second touch routing line RXRL2. The second touch routing line RXRL1 may be connected to a second main touch electrode MRX in an another pixel that is arranged spaced apart from each other in the first direction (Y-axis direction). Accordingly, the second touch routing line RXRL1 and the another second touch routing line RXRL2 can transmit touch signals sensed from pixels P (or second auxiliary touch electrodes STE2) arranged at different locations, respectively.

The second touch routing line RXRL1 and the another second touch routing line RXRL2 can be arranged in one touch area. Accordingly, each of the second touch routing line RXRL1 and the another second touch routing line RXRL2 can be connected to the upper pad UPAD in the non-display area NDA through each of the plurality of touch receiving electrode lines RXL. For example, assuming that the second touch routing line RXRL1 and the another second touch routing line RXRL2 are arranged on the 1a touch receiving electrode RX1a of FIG. 7, each of the second touch routing line RXRL1 and the another second touch routing line RXRL2 can be connected to each of the plurality of 1a touch receiving electrode lines RXL1a, and the plurality of 1a touch receiving electrode lines RXL1a can be connected to the upper pad UPAD in the non-display area NDA. Accordingly, the second touch routing line RXRL1 and the another second touch routing line RXRL2 can transmit a touch signal to the touch driver 210 through the upper pad UPAD.

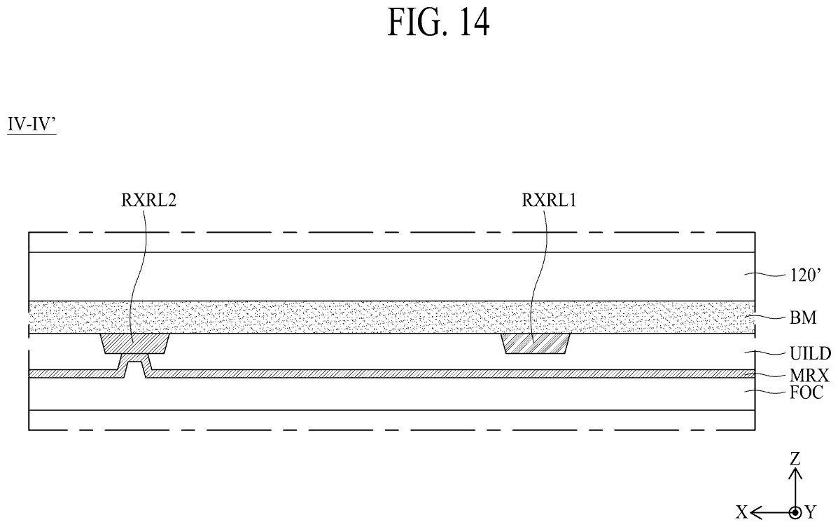

FIG. 14 is a partial cross-sectional view showing one example of IV-IV′ of FIG. 13.

Referring to FIG. 14, according to one example, the second touch routing line RXRL1 may not be electrically connected to an another second touch routing line RXRL2 in the touch area. For example, the second touch routing line RXRL1 may not be electrically connected to the another second touch routing line RXRL2 in the second touch area TUA2 (shown in FIG. 7) where the 1a touch receiving electrode RX1a is disposed.

As shown in FIG. 14, the another second touch routing line RXRL2 is connected to the second main touch electrode MRX, and the second main touch electrode MRX can be arranged to be spaced apart from the second touch routing line RXRL1 with the upper insulating layer UILD therebetween. That is, the another second touch routing line RXRL2 according to one example of FIG. 14 can be arranged closer to the black matrix BM than the second main touch electrode MRX. As shown in FIG. 14, since the second main touch electrode MRX is positioned spaced apart from the second touch routing line RXRL1 with the upper insulating layer UILD interposed therebetween, the second touch routing line RXRL1 may not be electrically connected to the another second touch routing line RXRL2 in the touch area. Although not shown, the second main touch electrode MRX may extend in the second direction (X-axis direction) and be connected to an another second touch routing line at a different location through an another contact hole formed in the upper insulating layer UILD. Accordingly, the transparent display apparatus 100 according to the second embodiment of the present disclosure can be provided so that the plurality of second touch routing lines RXRL1, RXRL2 that transmit touch signals sensed at different locations in one transmissive area do not interfere with each other. In this case, the second main touch electrode MRX may be made of a transparent conductive material such as ITO, but is not limited thereto and may be made of the same material as the another second touch routing line RXRL2. As shown in FIG. 14, the second main touch electrode MRX may be covered by the upper organic film FOC so as not to be exposed to the outside during the bonding process of the substrate 110 and the opposing substrate 120′. This structure and effect may be equally applied to the plurality of first touch routing lines.

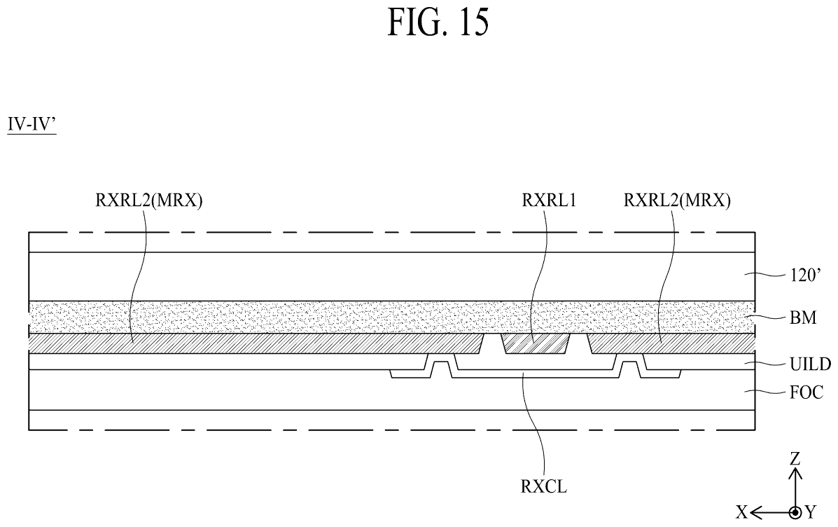

FIG. 15 is a partial cross-sectional view showing another example of IV-IV′ of FIG. 13.

Referring to FIG. 15, the second touch routing line RXRL1 according to another example may not be electrically connected to an another second touch routing line RXRL2 in the touch area. For example, the second touch routing line RXRL1 may not be electrically connected to the another second touch routing line RXRL2 in the second touch area TUA2 (shown in FIG. 7) where the 1a touch receiving electrode RX1a is disposed.

As shown in FIG. 15, two another second touch routing lines RXRL2 (or second main touch electrodes MRX) can be arranged spaced apart from each other in the second direction (X-axis direction) with the second touch routing line RXRL1 therebetween. In this case, two another second touch routing lines RXRL2 (or second main touch electrodes MRX) are arranged on the same layer as the second touch routing line RXRL1 and can be arranged closer to the black matrix BM than a second touch routing connection line RXCL. As shown in FIG. 15, the another second touch routing line RXRL2 (or a second main touch electrode MRX on a left side of the second touch routing line RXRL1) can be connected to one side of the second touch routing connection line RXCL through a contact hole penetrating the upper insulating layer UILD, and the other side of the second touch routing connection line RXCL can be connected to an another second touch routing line RXRL2 (or a second main touch electrode MRX on a right side of the second touch routing line RXRL1) through an another contact hole penetrating the upper insulating layer UILD. Accordingly, as shown in FIG. 15, two another second touch routing lines RXRL2 (or second main touch electrodes MRX) can be electrically connected to each other through the second touch routing connection line RXCL. And, since the second touch routing line RXRL1 is spaced apart from the second touch routing connection line RXCL with the upper insulating layer UILD therebetween, the second touch routing line RXRL1 may not be electrically connected to the another second touch routing line RXRL2 (or the second main touch electrode MRX) in the touch area. The second touch routing connection line RXCL serves to electrically connect two another second touch routing lines RXRL2 (or second main touch electrodes MRX) that are spaced apart from each other, and therefore can be expressed in terms of a touch routing bypass line. The second touch routing connection line RXCL may be made of a transparent conductive material such as ITO, but is not limited thereto, and may be made of the same opaque conductive material (or low-resistance metal material) as the another second touch routing line RXRL2.

Therefore, the transparent display apparatus 100 according to the second embodiment of the present disclosure can be provided so that the plurality of second touch routing lines RXRL1, RXRL2 that transmit touch signals sensed at different locations in one transmissive area do not interfere with each other, thereby improving touch sensitivity. As shown in FIG. 15, the second touch routing connection line RXRL can be covered by the upper organic film FOC so as not to be exposed to the outside during the bonding process. This structure and effect can be equally applied to the plurality of first touch routing lines.

Embodiments of the present disclosure have been described in more detail with reference to the accompanying drawings, but the present disclosure is not necessarily limited to these embodiments and may be implemented in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are exemplary in all respects and should be understood as non-limiting. The scope of protection of this disclosure shall be construed by the claims, and all technical ideas within the scope of the claims shall be construed to be included within the scope of the claims.

The present disclosure provides that the main touch electrode is provided to partially overlap with the black matrix, so that touch can be implemented while minimizing reduction in transmittance.

Furthermore, the present disclosure provides the auxiliary touch electrode in the transmissive area, so that touch sensitivity can be improved.

Furthermore, the present disclosure can be implemented in a large area while minimizing bezel increase by using the side connection electrodes on the sides of the substrate (or lower substrate) and the opposing substrate (or upper substrate) so that touch electrodes of the opposing substrate (or upper substrate) are connected to a touch driver of the substrate (or lower substrate).

Furthermore, the present disclosure can form the touch electrodes on the opposing substrate (or upper substrate) by utilizing a process line of the substrate (or lower substrate), production energy can be reduced through process optimization.

The effects that may be obtained from the present disclosure are not limited to those mentioned above, and other effects not mentioned will be apparent to one having ordinary skill in the art from the following description.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide examples of the technical features of the present disclosure for illustrative purposes. In other words, the disclosed embodiments are intended to illustrate the scope of the technical features of the present disclosure. Thus, the scope of the present disclosure is not limited to the embodiments shown, but is to be accorded the widest scope consistent with the claims. The scope of protection of the present disclosure should be construed based on the following claims, and all technical features within the scope of equivalents thereof should be construed as being included within the scope of the present disclosure.

What is claimed is:

1. A transparent display apparatus, comprising:
a substrate;
a display area in which a transmissive area and a plurality of subpixels are arranged;
a non-display area surrounding the display area;
a black matrix arranged on the substrate and between the plurality of subpixels and the transmissive area, and between the plurality of subpixels;
a main touch electrode partially overlapping the black matrix; and
an auxiliary touch electrode extending from the main touch electrode and arranged in the transmissive area.

2. The transparent display apparatus of claim 1, wherein the main touch electrode does not overlap any of the plurality of subpixels.

3. The transparent display apparatus of claim 1, wherein the main touch electrode is made of an opaque conductive material, and
wherein the auxiliary touch electrode is made of a transparent conductive material.

4. The transparent display apparatus of claim 1, wherein the auxiliary touch electrode is provided in a mesh form, and
wherein an edge of the auxiliary touch electrode is provided in a closed loop form.

5. The transparent display apparatus of claim 1, wherein the main touch electrode is disposed on the black matrix.

6. The transparent display apparatus of claim 1, wherein the auxiliary touch electrode is spaced further from the substrate than the main touch electrode.

7. The transparent display apparatus of claim 1,
wherein the plurality of subpixels are provided to emit different colors and include a first subpixel, a second subpixel, and a third subpixel sequentially arranged in a first direction,
wherein each of the first subpixel and the third subpixel is in a cross shape, and
wherein the second subpixel is in a square shape.

8. The transparent display apparatus of claim 1,
wherein the main touch electrode includes a plurality of first main touch electrodes and a plurality of second main touch electrodes spaced apart from the plurality of first main touch electrodes,
wherein the plurality of first main touch electrodes are arranged in a first touch area, and
wherein the plurality of second main touch electrodes are arranged in a second touch area.

9. The transparent display apparatus of claim 8,
wherein the first touch area is provided in a split form, and
wherein the second touch area is provided in a stripe form.

10. The transparent display apparatus of claim 1,
wherein each of the plurality of subpixels includes:
a pixel electrode arranged on the substrate;
an organic light-emitting layer arranged on the pixel electrode; and
a cathode electrode provided on the organic light-emitting layer,
wherein the organic light-emitting layer arranged on each of the plurality of subpixels is provided to emit different colors.

11. The transparent display apparatus of claim 1, wherein the main touch electrode is placed at a bottom of the black matrix.

12. The transparent display apparatus of claim 11, wherein the auxiliary touch electrode is positioned closer to the substrate than the main touch electrode.

13. The transparent display apparatus of claim 11,
wherein the plurality of subpixels include:
a first subpixel and a second subpixel, which are arranged sequentially in a first direction and are provided to emit different colors; and
a third subpixel and a fourth subpixel, which are arranged sequentially in the first direction and are provided to emit different colors from the first subpixel and the second subpixel,
wherein the third subpixel and the fourth subpixel are arranged adjacent to the first subpixel and the second subpixel in a second direction.

14. The transparent display apparatus of claim 11,
wherein each of the plurality of subpixels includes:
a pixel electrode arranged on the substrate;
an organic light-emitting layer arranged on the pixel electrode; and
a cathode electrode provided on the organic light-emitting layer, and
wherein the organic light-emitting layer arranged on each of the plurality of subpixels is provided to emit a same color.

15. The transparent display apparatus of claim 14, wherein each of the plurality of subpixels further includes a light emission area adjacent to the transmissive area,
wherein the cathode electrode is arranged in the light emission area and the transmissive area, and
wherein the cathode electrode arranged in the transmissive area is a floating electrode disconnected from the cathode electrode arranged in the light emission area.

16. The transparent display apparatus of claim 15, wherein the floating electrode partially overlaps the auxiliary touch electrode.

17. The transparent display apparatus of claim 1, further comprises:
a touch driving electrode line connected to the main touch electrode;
an upper pad connected to the touch driving electrode line;
an opposing substrate provided with the upper pad;
a lower pad provided on the substrate and arranged to face the upper pad; and
a side contact electrode connecting the upper pad and the lower pad.

18. The transparent display apparatus of claim 17, wherein the side contact electrode covers at least a portion of a side surface of the substrate and at least a portion of a side surface of the opposing substrate.

19. The transparent display apparatus of claim 1,
wherein the main touch electrode comprises a plurality of first main touch electrodes,
wherein the auxiliary touch electrode comprises a plurality of first auxiliary touch electrodes, and
wherein one first main touch electrode among the plurality of first main touch electrodes is connected to at least two or more of the first auxiliary touch electrodes.

20. The transparent display apparatus of claim 19, further comprising:
a first touch routing line connected to the first main touch electrode; and
another first touch routing line arranged parallel to the first touch routing line,
wherein the first touch routing line and the another first touch routing line are connected in the non-display area.

21. The transparent display apparatus of claim 1,
wherein the main touch electrode comprises a plurality of second main touch electrodes,
wherein the auxiliary touch electrode comprises a plurality of second auxiliary touch electrodes, and
wherein one second main touch electrode among the plurality of second main touch electrodes is connected to at least two or more of the second auxiliary touch electrodes.

22. The transparent display apparatus of claim 21, further comprising:
a second touch routing line connected to the second main touch electrode; and
another second touch routing line arranged parallel to the second touch routing line,
wherein each of the second touch routing line and the another second touch routing line is connected to an upper pad in the non-display area.

23. The transparent display apparatus of claim 22, wherein the second touch routing line is not electrically connected to the another second touch routing line in a touch area.
